(19) United States
(12) Patent Application Publication
(10) Pub. No.: US 2017/0235225 A1
(43) Pub. Date: Aug. 17, 2017

(54) COLORING COMPOSITION, COLORED CURED FILM, AND SOLID-STATE IMAGING ELEMENT

(71) Applicant: JSR CORPORATION, Minato-ku (JP)

(72) Inventors: Yuusuke MURATA, Minato-ku (JP); Kaori SAKAI, Minato-ku (JP); Yuuki SUEMITSU, Minato-ku (JP); Tomohiro TAKAMI, Minato-ku (JP); Shin-ichi OOTA, Minato-ku (JP); Masatsugu AYABE, Minato-ku (JP); Mibuko SHIMADA, Minato-ku (JP)

(73) Assignee: JSR CORPORATION, Minato-ku (JP)

(21) Appl. No.: 15/501,591

(22) PCT Filed: Aug. 4, 2015
(86) PCT No.: PCT/JP2015/072086

§ 371 Date: Feb. 3, 2017

(30) Foreign Application Priority Data
Aug. 11, 2014 (JP) 2014-163912
Aug. 11, 2014 (JP) 2014-163913

(51) Int. Cl. G03F 7/031; H01L 27/146; G03F 7/032; C09B 57/04; C09B 57/00

(52) U.S. Cl. CPC G03F 7/031; C09B 57/04; C09B 57/004; G03F 7/032; H01L 27/14621

(57) ABSTRACT

A coloring composition including: (A) a colorant; (C) a binder resin; (D) a polymerizable compound; and (F) a solvent, wherein

the colorant (A) comprises (A1) a pigment having a structure represented by the following Formula (X), and (A2) an isoindoline pigment, and

wherein the solvent (F) comprises (G) at least one member selected from the group consisting of an alcohol, a ketone, and an alkyl lactate:

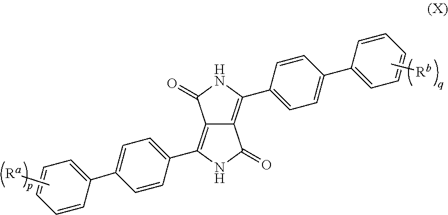

and wherein, in the Formula (X), R^{a} and R^{b} each independently represent a monovalent organic group, and p and q each independently represent an integer from 0 to 5.

### FIELD OF THE INVENTION

The present invention relates to a coloring composition, a colored cured film, and a solid-state imaging element, more particularly, it relates to a coloring composition that is used in the formation of a colored cured film to be used in a solid-state imaging element, a colored cured film formed by using the coloring composition, and a solid-state imaging element equipped with the colored cured film.

### BACKGROUND OF THE INVENTION

It is general to respectively dispose pixels of B (blue), G (green), and R (red) on the photodetector of a solid-state imaging element such as CCD or CMOS for color separation. As the ideal spectral properties of the pixel, it is required to have a decreased transmittance in the wavelength regions of other colors other than the color of the pixel and to exhibit excellent color separation property. For example, a red pixel is required to be a red pixel having a decreased transmittance in the blue to green wavelength region.

In addition, it is general to tone a color by using two or more kinds of pigments in order to obtain the color properties required to each pixel. For example, C.I. Pigment Red 177, C.I. Pigment Red 242, or C.I. Pigment Red 254 is used as a main pigment in a red pixel (for example, refer to Patent Documents 1 to 3).

In recent years, the color filter to be used in a solid-state imaging element is increasingly required to have a thinned pixel in order to increase the quantity of light reaching the light receiving portion for the improvement of light sensitivity.

In addition, in the color filter to be used in a solid-state imaging element, the pixel is also required to have a moderate rising to switch from the absorption region to the transmissive region in the transmission curve in order to obtain favorable color reproducibility.

### CITATION LIST

### Patent Documents

Patent Document 1: JP 9-325209 A
Patent Document 2: JP 11-14824 A
Patent Document 3: JP 2000-89025 A

### SUMMARY OF THE INVENTION

### Problems to be Solved by the Invention

Although an increase in concentration of the pigment is under investigations in order to cope with the requirement for thinning of film in recent years, it has become difficult to meet the requirement even if the technique to increase the concentration of the pigment in the prior art is simply applied in a situation in which the color filter is increasingly required to have color properties, for example, further thinning of pixels and improvement of color separation property.

In addition, according to the investigations by the present inventors, it has been revealed that it is difficult to fabricate a red pixel which exhibits both the color reproducibility and the color separation property by only using a pigment which has been so far used in the formation of a red pixel. In other words, in the case of using C.I. Pigment Red 254 as a main pigment, it is difficult to fabricate a red pixel which exhibits favorable color reproducibility since rising to switch from the absorption region to the transmissive region in the transmission curve is steep and also the transmissive region of the green pixel is affected since the transmittance in a wavelength region of from 520 nm to 540 nm slightly increases. Meanwhile, in the case of using C.I. Pigment Red 177 as a main pigment, the transmissive region of the green pixel is affected since the transmittance in a wavelength region of from 480 nm to 520 nm increases although rising to switch from the absorption region to the transmissive region in the transmission curve is more moderate as compared to the case of using C.I. Pigment Red 254. Furthermore, in the case of using C.I. Pigment Red 242 as a main pigment, the color separation property between the red pixel and the green pixel is affected since rising to switch from the absorption region to the transmissive region in the transmission curve is on a shorter wavelength side as compared to the case of using C.I. Pigment Red 254 although the transmittance in the green wavelength region is low. The “color separation property” used herein means to have spectral properties which hardly affect the transmissive region of the green pixel.

As described above, it is difficult to form a red pixel which exhibits both favorable color reproducibility and favorable color separation property in the case of using a red pigment which has been so far employed singly or concurrently using the red pigment as a main pigment and other pigments.

Accordingly, an object of the present invention is to provide a coloring composition suitable for forming a red pixel which exhibits favorable color reproducibility and hardly affects the transmissive region of a green pixel. Furthermore, an object of the present invention is to provide a red pixel formed by using the coloring composition and a solid-state imaging element equipped with the red pixel.

### Means for Solving the Problem

The present inventors have found out that the above object can be achieved by using a red pigment having a specific structure and an isoindoline pigment as a colorant and further containing a specific solvent as a result of intensive investigations.

That is, according to the present invention, there is provided a coloring composition including: (A) a colorant; (C) a binder resin; (D) a polymerizable compound; and (F) a solvent, wherein the coloring composition includes (A1) a pigment having a structure represented by the following Formula (X) and (A2) an isoindoline pigment as (A) the colorant, and

the coloring composition includes (G) at least one member selected from the group consisting of an alcohol, a ketone, and an alkyl lactate as (F) the solvent.

Further, according to the present invention, there is provided a colored cured film including: (A1) a pigment having a structure represented by the following Formula (X) ; and (A2) an isoindoline pigment, wherein the colored cured film satisfies anyone or more of the following conditions (1) to (4) at a film thickness of 0.5 μm.

(1) a transmittance at a wavelength of 400 nm is 30% or less.

(2) a maximum transmittance in a wavelength region of from 430 to 560 nm is 15% or less.

(3) a transmittance at a wavelength of 580 nm is 50% or less.

(4) a transmittance at a wavelength of 620 nm is 80% or more.

The present invention further provides a solid-state imaging element equipped with the colored cured film.

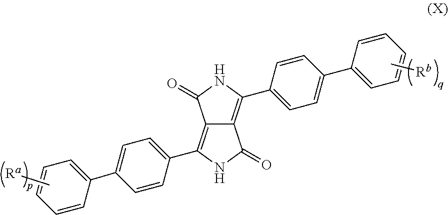

[In Formula (X),

R^{a} and R^{b} each independently represent a monovalent organic group, and

p and q each independently represent an integer from 0 to 5].

### Effects of the Invention

It is possible to form a red pixel which exhibits favorable color reproducibility and hardly affects the transmissive region of a green pixel by using the coloring composition of the present invention.

Consequently, the coloring composition of the present invention can be extremely suitably used in the fabrication of a solid-state imaging element such as a CMOS image sensor.

### BRIEF DESCRIPTION OF DRAWINGS

FIG. 1 is a view which illustrates the transmission spectra of the colored cured films obtained in Example 3 and Comparative Example 1 and a green cured film.

### DETAILED DESCRIPTION OF THE INVENTION

Hereinafter, the present invention will be described in detail.

### Coloring Composition

Hereinafter, the constituents of the coloring composition of the present invention will be described in detail.

### (A) Colorant

The coloring composition of the present invention essentially contains (A1) a pigment (hereinafter, also referred to as the “pigment X”) having a structure represented by the following Formula (X) and (A2) an isoindoline pigment as (A) a colorant.

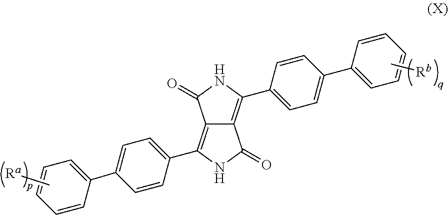

[In Formula (X), R^{a} and R^{b} each independently represent a monovalent organic group, and p and q each independently represent an integer from 0 to 5.]

The respective symbols in the formula of the pigment X will be described.

Examples of the monovalent organic group in R^{a} and R^{b} may include a hydrocarbon group and a group having a linking group containing an atom other than carbon and hydrogen atoms between the C—C bond in the hydrocarbon group. R^{a} and R^{b} may be the same as or different from each other.

Examples of the hydrocarbon group may include an aliphatic hydrocarbon group, an alicyclic hydrocarbon group, and an aromatic hydrocarbon group. Here, the “alicyclic hydrocarbon group” in the present specification is a concept to exclude an aliphatic hydrocarbon group which does not have acyclic structure. In addition, the “alicyclic hydrocarbon group” and the “aromatic hydrocarbon group” in the present specification are a concept which includes not only a group composed only of a ring structure but also a group in which the ring structure is further substituted with a divalent aliphatic hydrocarbon group, and it is sufficient for them to contain at least an alicyclic hydrocarbon or an aromatic hydrocarbon in the structure thereof. The hydrocarbon group may have a substituent, and examples of the substituent may include a halogen atom, a nitro group, a hydroxyl group, an amino group, an alkoxyl group, and an aryloxy group. Examples of the halogen atom may include a fluorine atom, a chlorine atom, a bromine atom, and an iodine atom. The alkoxyl group may be in any form of a straight chain or a branched chain, and examples thereof may include a methoxy group, an ethoxy group, a propoxy group, an isopropoxy group, a butoxy group, and a tert-butoxy group. Examples of the aryloxy group may include a phenoxy group and a benzyloxy group.

The aliphatic hydrocarbon group maybe saturated or unsaturated, and it may be straight-chain or branched-chain. Specific examples thereof may include an alkyl group, an alkenyl group, and an alkynyl group. The number of carbon atoms in the aliphatic hydrocarbon group is preferably from 1 to 30, more preferably from 1 to 24, and even more preferably from 1 to 20. Specific examples of the aliphatic hydrocarbon group may include an alkyl group such as a methyl group, an ethyl group, a propyl group, an isopropyl group, a butyl group, an isobutyl group, a sec-butyl group, or a tert-butyl group; an alkenyl group such as an ethenyl group, a 1-propenyl group, a 2-propenyl group, a 1-butenyl group, a 2-butenyl group, or a 1,3-butadienyl group; and an alkynyl group such as an ethynyl group, a 1-propynyl group, a 1-butynyl group, a 1-pentynyl group, or a 3-pentynyl group. The alicyclic hydrocarbon group may be saturated or unsaturated, and examples thereof may include a cycloalkyl group, a cycloalkenyl group, a condensed polycyclic hydrocarbon group, a bridged cyclic hydrocarbon group, a Spiro hydrocarbon group, and a cyclic terpene hydrocarbon group. The number of carbon atoms in the alicyclic hydrocarbon group is preferably from 3 to 30, more preferably from 3 to 12, and even more preferably from 6 to 12. Specific examples of the alicyclic hydrocarbon group may include a cycloalkyl group such as a cyclopropyl group, a cyclobutyl group, a cyclopentyl group, a cyclohexyl group, or a t-butylcyclohexyl; a cycloalkenyl group such as a 1-cyclohexenyl group; a condensed polycyclic hydrocarbon group such as a tricyclodecanyl group, a decahydro-2-naphthyl group, or an adamantyl group; a bridged cyclic hydrocarbon group such as a tricyclo[5.2.1.0^{2,6}]decane-8-yl group, a pentacyclopentadecanone group, an isobornyl group, a dicyclopentenyl group, or a tricyclopentenyl group; a spiro hydrocarbon group such as a monovalent group obtained by removing one hydrogen atom from spiro[3,4] heptane or spiro[3,4]octane; and a cyclic terpene hydrocarbon group such as a monovalent group obtained by removing one hydrogen atom from p-menthane, Thujane, or carane. Examples of the aromatic hydrocarbon group may include an aryl group. Here, the term “aryl group” in the present invention refers to a monocyclic to tricyclic aromatic hydrocarbon group, and the number of the carbon atoms therein is preferably from 6 to 20 and more preferably from 6 to 14. Specific examples of the aromatic hydrocarbon group may include a phenyl group, a benzyl group, an o-tolyl group, an m-tolyl group, a p-tolyl group, a xylyl group, a naphthyl group, an anthryl group, a phenanthryl group, an azulenyl group, and a 9-fluorenyl group.

Examples of the linking group in the group having a linking group containing an atom other than carbon and hydrogen atoms between the C—C bond in the hydrocarbon group may include —O—, —S—, —SO₂—, —CO—, —COO—, —OCO—, —CONR— (R represents a hydrogen atom or an alkyl group having from 1 to 6 carbon atoms), and —NR— (R is synonymous with the above). It is possible to have one member or two or more members of linking groups. The bonding position of the linking group is arbitrary, and for example, it is possible to have the linking group at the terminal of the hydrocarbon group or between the C—C bond therein, and the hydrocarbon group may be bonded with the linking group to form a ring structure.

Among them, a hydrocarbon group is preferable, an aromatic hydrocarbon group is more preferable, and a phenyl group is even more preferable as R^{a} and R^{b}.

p and q each independently represent an integer from 0 to 5, but 1 or 2 is preferable and 1 is more preferable.

As the pigment X, for example, C.I. Pigment Red 2 64 can be mentioned as a suitable pigment in the compounds that are classified as a pigment in the color index (C.I.; issued by The Society of Dyers and Colourists), namely, those with a color index (C.I.) number.

Examples of the isoindoline pigment may include C.I. Pigment Yellow 139 and C.I. Pigment Yellow 185. By concurrently using an isoindoline pigment as a colorant, it is possible to decrease the transmittance at a wavelength region of from 400 to 560 nm and thus to form a red pixel having a decreased transmittance in the blue to green wavelength region. Among them, C.I. Pigment Yellow 185 is preferable from the viewpoint of an even more decrease in transmittance in a wavelength region of from 400 to 560 nm.

The proportion of (A1) the pigment X and (A2) the isoindoline pigment contained can be appropriately set, but it is preferably from 85/15 to 65/35 as the mass ratio [(A1)/(A2)] of the component (A1) to the component (A2) from the viewpoint of forming a red pixel which exhibits excellent color reproducibility, has a high transmittance, and hardly affects the transmissive region of a green color. In addition, the mass ratio [(A1)/(A2)] is preferably from 80/20 to 65/35, more preferably from 75/25 to 65/35, and even more preferably from 70/30 to 65/35 from the viewpoint of even further decreasing the transmittance in the blue wavelength region. Furthermore, the mass ratio [(A1)/(A2)] is preferably from 85/15 to 70/30, more preferably from 85/15 to 75/25, and even more preferably from 85/15 to 80/20 from the viewpoint of even further decreasing the transmittance in the green wavelength region. Meanwhile, the mass ratio [(A1)/(A2)] is preferably from. 85/15 to 70/30 and more preferably from 80/20 to 70/30 from the viewpoint of forming a red pixel which has a decreased transmittance in the blue to green wavelength region in a favorable balance.

The coloring composition of the present invention may contain other colorants other than (A1) the pigment X and (A2) the isoindoline pigment to an extent in which the effect of the present invention is not affected. Specific examples thereof may include a pigment that is classified as a pigment in the color index (C.I.; issued by The Society of Dyers and Colourists) and a dye.

Examples of such a pigment may include those with the color index (C.I.) numbers as follows.

Red pigments other than C.I. Pigment Red 264 such as C.I. Pigment Red 1, C.I. Pigment Red 2, C.I. Pigment Red 5, C.I. Pigment Red 17, C.I. Pigment Red 31, C.I. Pigment Red 32, C.I. Pigment Red 41, C.I. Pigment Red 48:1, C.I. Pigment Red 48:2, C.I. Pigment Red 48:3, C.I. Pigment Red 48:4, C.I. Pigment Red 48:5, C.I. Pigment Red 49, C.I. Pigment Red 49:1, C.I. Pigment Red 49:2, C.I. Pigment Red 49:3, C.I. Pigment Red 52:1, C.I. Pigment Red 52:2, C.I. Pigment Red 53:1, C.I. Pigment Red 54, C.I. Pigment Red 57:1, C.I. Pigment Red 58, C.I. Pigment Red 58:1, C.I. Pigment Red 58:2, C.I. Pigment Red 58:3, C.I. Pigment Red 58:4, C.I. Pigment Red 60:1, C.I. Pigment Red 63, C.I. Pigment Red 63:1, C.I. Pigment Red 63:2, C.I. Pigment Red 63:3, C.I. Pigment Red 64:1, C.I. Pigment Red 68, C.I. Pigment Red 81, C.I. Pigment Red 81:1, C.I. Pigment Red 122, C.I. Pigment Red 123, C.I. Pigment Red 144, C.I. Pigment Red 149, C.I. Pigment Red 166, C.I. Pigment Red 168, C.I. Pigment Red 170, C.I. Pigment Red 171, C.I. Pigment Red 175, C.I. Pigment Red 176, C.I. Pigment Red 177, C.I. Pigment Red 178, C.I. Pigment Red 179, C.I. Pigment Red 180, C.I. Pigment Red 185, C.I. Pigment Red 187, C.I. Pigment Red 200, C.I. Pigment Red 202, C.I. Pigment Red 206, C.I. Pigment Red 207, C.I. Pigment Red 209, C.I. Pigment Red 214, C.I. Pigment Red 220, C.I. Pigment Red 221, C.I. Pigment Red 224, C.I. Pigment Red 237, C.I. Pigment Red 239, C.I. Pigment Red 242, C.I. Pigment Red 243, C.I. Pigment Red 247, C.I. Pigment Red 254, C.I. Pigment Red 255, C.I. Pigment Red 262, and C.I. Pigment Red 272;

Yellow pigments other than the isoindoline pigment such as C.I. Pigment Yellow 12, C.I. Pigment Yellow 13, C.I. Pigment Yellow 14, C.I. Pigment Yellow 17, C.I. Pigment Yellow 20, C.I. Pigment Yellow 24, C.I. Pigment Yellow 31, C.I. Pigment Yellow 55, C.I. Pigment Yellow 61, C.I. Pigment Yellow 61:1, C.I. Pigment Yellow 62, C.I. Pigment Yellow 83, C.I. Pigment Yellow 93, C.I. Pigment Yellow 100, C.I. Pigment Yellow 104, C.I. Pigment Yellow 109, C.I. Pigment Yellow 110, C.I. Pigment Yellow 129, C.I. Pigment Yellow 133, C.I. Pigment Yellow 138, C.I. Pigment Yellow 150, C.I. Pigment Yellow 153, C.I. Pigment Yellow 154, C.I. Pigment Yellow 155, C.I. Pigment Yellow 166, C.I. Pigment Yellow 168, C.I. Pigment Yellow 169, C.I. Pigment Yellow 180, C.I. Pigment Yellow 183, C.I. Pigment Yellow 191, C.I. Pigment Yellow 191:1, C.I. Pigment Yellow 206, C.I. Pigment Yellow 209, C.I. Pigment Yellow 209:1, C.I. Pigment Yellow 211, C.I. Pigment Yellow 212, and C.I. Pigment Yellow 215.

Examples of the red dye may include a xanthene compound, a triarylmethane compound, a cyanine compound, an anthraquinone compound, and a dipyrromethene compound. In addition, examples of the yellow dye may include an anthraquinone compound, an azo compound, an azomethine compound, and a quinophthalone compound. Specific examples thereof may include the compounds that are classified as a dye in the color index (C.I.; issued by The Society of Dyers and Colourists).

The proportion of other colorants contained is preferably 30 mass % or less, more preferably 10 mass % or less, and even more preferably 5 mass % or less with respect to the total content of (A) the colorant.

In the present invention, (A1) the pigment X, (A2) the isoindoline pigment, and other pigments to be arbitrarily mixed can also be used after being purified by a recrystallization method, a reprecipitation method, a solvent washing method, a sublimation method, a vacuum heating method, or a combination thereof. In addition, these pigments may be used after the particle surface thereof is modified with a resin if desired. Examples of the resin that is used to modify the particle surface of the pigment may include a vehicle resin described in JP 2001-108817 A or various kinds of commercially available resins for pigment dispersion. In addition, an organic pigment may be used after the primary particles thereof are refined by the so-called salt milling. As a method for salt milling, for example, it is possible to employ the method disclosed in JP 08-179111 A.

In the present invention, it is possible to contain other pigments to be arbitrarily mixed as (A) the colorant in addition to (A1) the pigment X and (A2) the isoindoline pigment, but the average particle size of the pigments contained in the colorant is preferably from 15 to 100 nm, more preferably from 20 to 80 nm, and even more preferably from 20 to 55 nm. By having such an aspect, a colored cured film exhibiting sufficient surface smoothness can be formed. Here, the “ average particle size of the pigment” in the present specification is a value obtained by measuring the length of 100 primary particles present in the visual field observed through a transmission electron microscope and calculating the average value thereof.

In the present invention, it is possible to further contain a known dispersion auxiliary together with (A1) the pigment X, (A2) the isoindoline pigment, and other colorants to be arbitrarily mixed.

Examples of the dispersion auxiliary may include a pigment derivative. As the pigment derivative, a pigment derivative having an acidic functional group is preferable from the viewpoint of obtaining a coloring composition which exhibits excellent developability. Examples of the acidic functional group may include a sulfo group, a carboxyl group, and a phosphoric acid group, but a sulfo group and a carboxyl group are more preferable, and a sulfo group is even more preferable. Specific examples thereof may include a sulfonic acid derivative such as copper phthalocyanine, diketopyrrolopyrrole, and quinophthalone.

The proportion of the dispersion auxiliary contained is preferably from 0.1 to 10 mass %, more preferably from 0.2 to 5 mass %, and even more preferably from 0.5 to 3 mass % with respect to the total content of (A) the colorant from the viewpoint of forming a red pixel which exhibits excellent color reproducibility, has a high transmittance, and hardly affects the transmissive region of other colors.

The proportion of (A) the colorant contained is usually from 5 to 70 mass %, preferably from 30 to 60 mass %, more preferably from 40 to 55 mass %, and even more preferably from 45 to 55 mass % in the solids of the coloring composition from the viewpoint of forming a red pixel which exhibits excellent color reproducibil ity, has a high transmittance, and hardly affects the transmissive region of other colors. Here, the solids are components other than the solvent to be described later.

### (B) Dispersant

In the present invention, it is possible to further contain (B) a dispersant together with (A1) the pigment X, (A2) the isoindoline pigment, and other colorants to be arbitrarily mixed.

Examples of (B) the dispersant may include a urethane-based dispersant, a polyethyleneimine-based dispersant, a polyoxyalkylene alkyl ether-based dispersant, a polyoxyalkylene alkyl phenyl ether-based dispersant, a dispersant containing a repeating unit having an alkylene oxide structure, a poly(alkylene glycol) diester-based dispersant, a sorbitan fatty acid ester-based dispersant, a polyester-based dispersant, and a (meth)acrylic dispersant. As a commercially available product, for example, it is possible to use a (meth)acrylic dispersant such as the DISPERBYK-2000, DISPERBYK-2001, BYK-LPN6919,BYK-LPN21116,or BYK-LPN22102 (all of them are manufactured by BYK), a urethane-based dispersant such as the DISPERBYK-161, DISPERBYK-162, DISPERBYK-165, DISPERBYK-167, DISPERBYK-170, or DISPERBYK-182 (all of them are manufactured by BYK) or the Solsperse 76500 (manufactured by Lubrizol Corporation), a polyethyleneimine-based dispersant such as the Solsperse 24000 (manufactured by Lubrizol Corporation), a polyester dispersant such as the AJISPER PB821, AJISPER PB822, AJISPER PB880, or AJISPER PB881 (all of them are manufactured by Ajinomoto Fine-Techno Co., Inc.), and the BYK-LPN21324 (manufactured by BYK).

Among them, (B1) a dispersant containing a repeating unit having an alkylene oxide structure is preferable as (B) the dispersant from the viewpoint of forming a red pixel which has fewer development residues.

As (B1) the dispersant containing a repeating unit having an alkylene oxide structure, a copolymer of an ethylenically unsaturated monomer represented by the following Formula (1) (hereinafter, also referred to as the “unsaturated monomer (b1)”) and another copolymerizable ethylenically unsaturated monomer (hereinafter, also referred to as the “unsaturated monomer (b2)”) is more preferable.

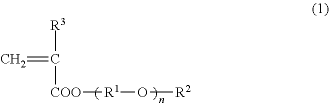

[In Formula (1), R¹ represents an alkanediyl group having from 2 to 3 carbon atoms, R² represents an alkyl group having from 1 to 5 carbon atoms, R³ represents a hydrogen atom or a methyl group, n is an integer from 1 to 20. A plurality of R¹s maybe the same as or different from one another in a case in which n is 2 or more.

Examples of R¹ may include an ethylene group, a 1,2-propanediyl group, and a 1,3-propanediyl group, and an ethylene group and a 1,2-propanediyl group are preferable among them.

Examples of the alkyl group of R² may include a methyl group, an ethyl group, a propyl group, an isopropyl group, a butyl group, an isobutyl group, a sec-butyl group, and a tert-butyl group. Among them, a methyl group, an ethyl group, a propyl group, and a butyl group are preferable.

n is preferably from 1 to 10 and more preferably from 1 to 5.

Examples of the unsaturated monomer (b1) may include polyethylene glycol (n=1 to 5) methyl ether (meth)acrylate, polyethylene glycol (n=1 to 5) ethyl ether (meth)acrylate, polyethylene glycol (n=1 to 5) propyl ether (meth)acrylate, polypropylene glycol (n=1 to 5) methyl ether (meth)acrylate, polypropylene glycol (n=1 to 5) ethyl ether (meth)acrylate, and polypropylene glycol (n=1 to 5) propyl ether (meth)acrylate.

Examples of the unsaturated monomer (b2) may include the same ones as the unsaturated monomer (c1) and the unsaturated monomer (c2) to be described later, and it is preferable to contain a (meth)acrylate other than the unsaturated monomer (b1) among them.

In (B1) the dispersant containing a repeating unit having an alkylene oxide structure, the proportion of the repeating unit having an alkylene oxide structure contained is preferably from 3 to 40 mass % in the total repeating units from the viewpoint of forming a red pixel which has even fewer development residues, it is more preferably from 5 to 35 mass %, even more preferably from 7 to 30 mass %, even more preferably from 10 to 27 mass %, and even more preferably from 13 to 27 mass %.

In addition, the weight average molecular weight (Mw) of (B1) the dispersant containing a repeating unit having an alkylene oxide structure in terms of polystyrene measured by gel permeation chromatography (hereinafter, abbreviated as GPC) (eluent: tetrahydrofuran) is usually from 1,000 to 50,000 and preferably 5,000 to 30,000.

In the present invention, (B) the dispersant may be used singly or as a mixture of two or more members thereof.

(B) the dispersant is preferably one that has an amine value of from 10 to 200 mg KOH/g, one that has an amine value of from 50 to 180 mg KOH/g is even more preferable, and one that has an amine value of from 80 to 150 mg KOH/g is even more preferable. The “amine value” in the present invention represents KOH in mg of an equivalent amount with an acid required to neutralize 1 g of the dispersant solids.

In the present invention, the content of (B) the dispersant is preferably from 5 to 300 parts by mass, more preferably from 10 to 200 parts by mass, even more preferably from 20 to 100 parts by mass, and even more preferably from 20 to 50 parts by mass with respect to 100 parts by mass of (A) the colorant.

In the case of using (B1) the dispersant containing a repeating unit having an alkylene oxide structure, the proportion of (B1) the dispersant containing a repeating unit having an alkylene oxide structure contained is preferably 50 mass % or more and more preferably 80 mass % or more with respect to the total content of (B) the dispersant.

### (C) Binder Resin

(C) the binder resin in the present invention is not particularly limited, but it is preferably a resin having an acidic functional group such as a carboxyl group or a phenolic hydroxyl group. Among them, a polymer having a carboxyl group (hereinafter, also referred to as the “carboxyl group-containing polymer”) is preferable, and examples thereof may include a copolymer of an ethylenically unsaturated monomer having one or more carboxyl groups (hereinafter, also referred to as the “unsaturated monomer (c1) ”) and another copolymerizable ethylenically unsaturated monomer (hereinafter, also referred to as the “unsaturated monomer (c2)”).

Examples of the unsaturated monomer (c1) may include (meth)acrylic acid, maleic acid, maleic anhydride, mono [2-(meth)acryloyloxyethyl] succinate, ω-carboxypolycaprolactone mono(meth)acrylate, and p-vinyl benzoate.

These unsaturated monomers (c1) may be used singly or as a mixture of two or more members thereof.

In addition, examples of the unsaturated monomer (c2) may include a maleimide substituted at the position of N such as N-phenylmaleimide or N-cyclohexylmaleimide; an aromatic vinyl compound such as styrene, α-methylstyrene, p-hydroxystyrene, p-hydroxy-α-methylstyrene, p-vinyl benzyl glycidyl ether, or acenaphthylene;

A (meth)acrylate such as methyl (meth)acrylate, n-butyl (meth)acrylate, 2-ethylhexyl (meth)acrylate, 2-hydroxyethyl (meth)acrylate, allyl (meth)acrylate, benzyl (meth)acrylate, polyethylene glycol (degree of polymerization of 2 to 10) methyl ether (meth)acrylate, polypropylene glycol (degree of polymerization of 2 to 10) methyl ether (meth)acrylate, polyethylene glycol (degree of polymerization of 2 to 10) mono(meth)acrylate, polypropylene glycol (degree of polymerization of 2 to 10) mono(meth)acrylate, cyclohexyl (meth acrylate, isobornyl (meth)acrylate, tricyclo[5.2.1.0^{2,6}]decane-8-yl (meth)acrylate, dicyclopentenyl (meth)acrylate, glycerol mono(meth)acrylate, 4-hydroxyphenyl (meth)acrylate, ethylene oxide-modified (meth)acrylate of p-cumylphenol, glycidyl (meth)acrylate, 3,4-epoxycyclohexylmethyl (meth)acrylate, 3-[(meth)acryloyloxymethyl]oxetane, or 3-[(meth)acryloyloxymethyl]-3-ethyloxetane;

A vinyl ether such as cyclohexyl vinyl ether, isobornyl vinyl ether, tricyclo[5.2.1.0^{2,6}]decane-8-yl vinyl ether, pentacyclopentadecanone vinyl ether, or 3-(vinyloxymethyl)-3-ethyloxetane; and a macromonomer having a mono(meth)acryloyl group at the terminal of the molecular chain of a polymer such as polystyrene, polymethyl (meth)acrylate, poly-n-butyl (meth)acrylate, or polysiloxane.

These unsaturated monomers (c2) maybe used singly or as a mixture of two or more members thereof.

In the copolymer of the unsaturated monomer (c1) and the unsaturated monomer (c2), the proportion of the unsaturated monomer (c1) copolymerized in the copolymer is preferably from 5 to 50 mass % and more preferably from 10 to 40 mass %. By copolymerizing the unsaturated monomer (c1) in such a range, it is possible to obtain a coloring composition which exhibits excellent alkali developability and storage stability.

Specific examples of the copolymer of the unsaturated monomer (c1) and the unsaturated monomer (c2) may include copolymers that are disclosed in JP 7-140654 A, JP 8-259876 A, JP 10-31308 A, JP 10-300922 A, JP 11-174224 A, JP 11-258415 A, JP 2000-56118 A, and JP 2004-101728 A.

In the present invention, it is preferable to use a carboxyl group-containing polymer having a polymerizable unsaturated bond such as a (meth)acryloyl group in the side chain as (C) the binder resin from the viewpoint of smoothness of the cured film. Examples of such a polymer may include those that are disclosed in JP 5-19467 A, JP 6-230212 A, JP 7-207211 A, JP 9-325494 A, JP 11-140144 A, and JP 2008-181095 A.

Examples of such a carboxyl group-containing polymer having a polymerizable unsaturated bond such as a (meth)acryloyl group in the side chain may include the following polymers i) to iv), and it is possible to contain at least one member selected from the group consisting of the following polymers i) to iv).

i) A polymer obtained by reacting an unsaturated isocyanate compound with a polymer of a monomer containing the unsaturated monomer (c1) and a polymerizable unsaturated compound having a hydroxyl group,

ii) A polymer obtained by reacting a polymerizable unsaturated compound having an oxiranyl group with a polymer of a monomer containing the unsaturated monomer (c1),

iii) A polymer obtained by reacting the unsaturated monomer (c1) with a polymer of a monomer containing a polymerizable unsaturated compound having an oxiranyl group and the unsaturated monomer (c1), and

iv) A polymer obtained by reacting the unsaturated monomer (c1) with a polymer of a monomer containing a polymerizable unsaturated compound having an oxiranyl group and further reacting a polybasic acid anhydride with the resultant.

It is also possible to further react a polybasic acid anhydride with the hydroxyl group produced by the reaction between the unsaturated monomer (c1) and an oxiranyl group.

Examples of the unsaturated isocyanate compound may include those described in the paragraph [0049] of JP 2010-044365 A.

Examples of the polymerizable unsaturated compound having an oxiranyl group may include those described in the paragraph [0053] of JP 2010-044365 A.

Examples of the polybasic acid anhydride may include those described in the paragraph [0067] of JP 2014-098140 A.

The weight average molecular weight (Mw) of (C) the binder resin in the present invention in terms of polystyrene measured by gel permeation chromatography (hereinafter, abbreviated as GPC) (eluent: tetrahydrofuran) is usually from 1,000 to 100, 000 and preferably from 3,000 to 50,000. By having such an aspect, the residual film rate of the coating film, the pattern shape, the heat resistance, the electrical properties, and the resolution are even further enhanced, and the generation of dry foreign matters at the time of coating can also be suppressed at a high level.

In addition, the ratio (Mw/Mn) of the weight average molecular weight (Mw) to the number average molecular weight (Mn) of (C) the binder resin in the present invention is preferably from 1.0 to 5.0 and more preferably from 1.0 to 3.0. Mn used herein is the number average molecular weight in terms of polystyrene measured by GPC (eluent: tetrahydrofuran).

(C) the binder resin in the present invention can be produced by a known method, but it is also possible to control the structure, Mw, and Mw/Mn by the methods that are disclosed, for example, in JP 2003-222717 A, JP 2006-259680 A, and WO 2007/029871 A.

In the present invention, (C) the binder resin may be used singly or as a mixture of two or more members thereof.

In the present invention, the content of (C) the binder resin is usually from 10 to 1,000 parts by mass, preferably from 15 to 500 parts by mass, and more preferably 20 to 150 parts by mass with respect to 100 parts by mass of (A) the colorant. By having such an aspect, it is possible to enhance the alkali developability, storage stability of the coloring composition, the pattern shape, and the chromaticity properties in addition to even further improvement of tinting strength.

### (D) Polymerizable Compound

In the present invention, (D) the polymerizable compound is a compound having two or more polymerizable groups. Examples of the polymerizable group may include an ethylenically unsaturated group, an oxiranyl group, an oxetanyl group, and an N-alkoxymethylamino group. In the present invention, as the polymerizable compound, a compound having two or more (meth)acryloyl groups or a compound having two or more N-alkoxymethylamino groups are preferable.

Specific examples of the compound having two or more (meth)acryloyl groups may include a multi functional (meth)acrylate obtained by reacting an aliphatic polyhydroxy compound and (meth)acrylic acid, a caprolactone-modified multifunctional (meth)acrylate, an alkylene oxide-modified multifunctional (meth)acrylate, a multifunctional urethane (meth)acrylate obtained by reacting a (meth)acrylate having a hydroxyl group with a multi functional isocyanate, and a multi functional (meth)acrylate which has a carboxyl group and is obtained by reacting a (meth)acrylate having a hydroxyl group with an acid anhydride.

Here, examples of the aliphatic polyhydroxy compound may include a divalent aliphatic polyhydroxy compound such as ethylene glycol, propylene glycol, polyethylene glycol, or polypropylene glycol; a trivalent or higher aliphatic polyhydroxy compound such as glycerol, trimethylolpropane, pentaerythritol, or dipentaerythritol. Examples of the (meth)acrylate having a hydroxyl group may include 2-hydroxyethyl (meth)acrylate, trimethylolpropane di(meth)acrylate, pentaerythritol tri(meth)acrylate, dipentaerythritol penta(meth)acrylate, and glycerol dimethacrylate. Examples of the multifunctional isocyanate may include tolylene diisocyanate, hexamethylene diisocyanate, diphenylmethylene diisocyanate, and isophorone diisocyanate. Examples of the acid anhydride may include an anhydride of a dibasic acid such as succinic anhydride, maleic anhydride, glutaric anhydride, itaconic anhydride, phthalic anhydride, or hexahydrophthalic anhydride and a tetrabasic acid dianhydride such as pyromellitic dianhydride, biphenyltetracarboxylic dianhydride, or benzophenonetetracarboxylic dianhydride.

In addition, examples of the caprolactone-modified multifunctional (meth)acrylate may include the compounds described in the paragraphs [0015] to [0018] of JP 11-44955A. Examples of the alkylene oxide-modified multifunctional (meth)acrylate may include bisphenol A di(meth)acrylate that is modified with at least one member selected from ethylene oxide and propylene oxide, isocyanuric acid tri(meth)acrylate that is modified with at least one member selected from ethylene oxide and propylene oxide, trimethylolpropane tri(meth)acrylate that is modified with at least one member selected from ethylene oxide and propylene oxide, pentaerythritol tri(meth)acrylate that is modified with at least one member selected from ethylene oxide and propylene oxide, pentaerythritol tetra (meth)acrylate that is modified with at least one member selected from ethylene oxide and propylene oxide, dipentaerythritol penta (meth)acrylate that is modified with at least one member selected from ethylene oxide and propylene oxide, and dipentaerythritol hexa(meth)acrylate that is modified with at least one member selected from ethylene oxide and propylene oxide.

In addition, examples of the compound having two or more N-alkoxymethylamino groups may include compounds having a melamine structure, a benzoguanamine structure, and a urea structure. The melamine structure and the benzoguanamine structure refer to a chemical structure having one or more triazine ring or phenyl-substituted triazine ring as a basic scaffold, and they are a concept which includes melamine, benzoguanamine, or any condensate thereof. Specific examples of the compound having two or more N-alkoxymethylamino groups may include N,N,N′,N′,N″,N″-hexa(alkoxymethyl)melamine, N,N,N′,N′-tetra(alkoxymethyl)benzoguanamine, and N,N,N′,N′-tetra(alkoxymethyl)glycoluril.

Among these polymerizable compounds, an alkylene oxide-modified multifunctional (meth)acrylate and a multifunctional (meth)acrylate having a carboxyl group are preferable from the viewpoint of forming a red pixel which has fewer development residues, and an alkylene oxide-modified multifunctional (meth)acrylate is more preferable.

Among the alkylene oxide-modified multifunctional (meth)acrylates, trimethylolpropane tri (meth)acrylate that is modified with at least one member selected from ethylene oxide and propylene oxide, pentaerythritol tetra(meth)acrylate that is modified with at least one member selected from ethylene oxide and propylene oxide, dipentaerythritol penta(meth)acrylate that is modified with at least one member selected from ethylene oxide and propylene oxide, and dipentaerythritol hexa(meth)acrylate that is modified with at least one member selected from ethylene oxide and propylene oxide are preferable.

Among the multi functional (meth)acrylates having a carboxyl group, a compound obtained by reacting pentaerythritol triacrylate with succinic anhydride and a compound obtained by reacting dipentaerythritol pentaacrylate with succinic anhydride are preferable.

In the present invention, (D) the polymerizable compound may be used singly or as a mixture of two or more members thereof.

In a case in which (D) the polymerizable compound contains at least one member selected from the group consisting of an alkylene oxide-modified multifunctional (meth)acrylate and a multifunctional (meth)acrylates having a carboxyl group, the proportion of at least one member selected from the group consisting of an alkylene oxide-modified multifunctional (meth)acrylate and a multifunctional (meth)acrylates having a carboxyl group contained is preferably 40 mass % or more, more preferably 50 mass % or more, and even more preferably 70 mass % or more with respect to the total amount of the component (D).

The content of (D) the polymerizable compound in the present invention is preferably from 10 to 1,000 parts by mass, more preferably from 30 to 300 parts by mass, even more preferably from 50 to 200 parts by mass, and even more preferably from 80 to 125 parts by mass with respect to 100 parts by mass of (C) the binder resin. By having such an aspect, the curability and alkali developability are further enhanced and the generation, for example, of greasing and residual film on the substrate of the unexposed portion or the light-shielding layer can be suppressed at a high level in addition to even further improvement of the tinting strength.

### (E) Photopolymerization Initiator

The coloring composition of the present invention can contain (E) a photopolymerization initiator. This makes it possible to impart radiation sensitive property to the coloring composition. The photopolymerization initiator to be used in the present invention is a compound which generates an active species capable of initiating polymerization of the polymerizable compound by being exposed to radiation such as visible light, ultraviolet light, far ultraviolet light, electron beams, and X-rays.

Examples of such a photopolymerization initiator may include a thioxanthone compound, an acetophenone compound, a biimidazole compound, a triazine compound, an O-acyloxime compound, an onium salt compound, a benzoin compound, a benzophenone compound, an α-diketone compound, a polynuclear quinone compound, a diazo compound, and an imidosulfonate compound. In the present invention, (E) the photopolymerization initiator may be used singly or as a mixture of two or more members thereof.

Among them, it is preferable to contain at least one member selected from the group consisting of a thioxanthone compound, an acetophenone compound, a biimidazole compound, a triazine compound, and an O-acyloxime compound as (E) the photopolymerization initiator, and it is more preferable to contain at least one member of compound selected from the group consisting of (E1) an O-acyloxime-based compound and (E2) a thioxanthone-based compound and an acetophenone-based compound from the viewpoint of forming a pixel having a low surface roughness.

Specific examples of the (E1) the O-acyloxime compound may include 1,2-octanedione, 1-[4-(phenylthio)phenyl]-, 2-(O-benzoyloxime), ethanone, 1-[9-ethyl-6-(2-methylbenzoyl)-9H-carbazol-3-yl]-, 1-(O-acetyloxime), ethanone, 1-[9-ethyl-6-(2-methyl-4-tetrahydrofuranylmethoxybenzoyl)-9H-carbazol-3-yl]-, 1-(O-acetyloxime), ethanone, 1-[9-ethyl-6-{2-methyl-4-(2,2-dimethyl-1,3-dioxolanyl)methoxybenzoyl}-9H-carbazol-3-yl]-, 1-(O-acetyloxime). As commercially available products of (E1) the O-acyloxime compound, for example, the NCI-831 and NCI-930 (both of them are manufactured by ADEKA CORPORATION) and the DFI-020 and DFI-091 (both of them are manufactured by DAITO CHEMIX Co., Ltd.) can be used. Among these, 1,2-octanedione, 1-[4-(phenylthio)phenyl]-, 2-(O-benzoyloxime), ethanone, 1-[9-ethyl-6-(2-methylbenzoyl)-9H-carbazol-3-yl]-, 1-(O-acetyloxime), the NCI-831, and the NCI-930 are preferable, and 1,2-octanedione, 1-[4-(phenylthio)phenyl]-, 2-(O-benzoyloxime) is more preferable.

Specific examples of the thioxanthone compound among the components (E2) in the present invention may include thioxanthone, 2-chlorothioxanthone, 2-methylthioxanthone, 2-isopropylthioxanthone, 4-isopropylthioxanthone, 2,4-dichlorothioxanthone, 2,4-dimethylthioxanthone, 2,4-diethylthioxanthone, and 2,4-diisopropylthioxanthone.

In addition, specific examples of the acetophenone compound among the components (E2) in the present invention may include 2-methyl-1-[4-(methylthio)phenyl]-2-morpholinopropane-1-one, 2-benzyl-2-dimethylamino-1-(4-morpholinophenyl)butan-1-one, and 2-(4-methylbenzyl)-2-(dimethylamino)-1-(4-morpholinophenyl)butan-1-one.

The proportion of the component (E1) and component (E2) contained can be appropriately set, but it is preferably from 20/80 to 80/20 as the mass ratio [(E1)/(E2)] and it is more preferably from 30/70 to 70/30 from the viewpoint of forming a pixel having a lower surface roughness.

In addition, specific examples of the biimidazole compound may include 2,2′-bis(2-chlorophenyl)-4,4′,5,5′-tetraphenyl-1,2′-biimidazole, 2,2′-his(2,4-dichlorophenyl)-4,4′,5,5′-tetraphenyl-1,2′-biimidazole, and 2,2′-bis(2,4,6-trichlorophenyl)-4,4′,5,5′-tetraphenyl-1,2′-biimidazole.

In the case of using a biimidazole compound as a photopolymerization initiator, it is preferable to concurrently use a hydrogen donor from the viewpoint of being able to improve the sensitivity. The term “hydrogen donor” used herein means a compound capable of donating a hydrogen atom to a radical generated from a biimidazole compound by exposure. Examples of the hydrogen donor may include a mercaptan hydrogen donor such as 2-mercaptobenzothiazole or 2-mercaptobenzoxazole and an amine hydrogen donor such as 4,4′-bis (dimethylamino)benzophenone or 4,4′-bis(diethylamino)benzophenone. In the present invention, the hydrogen donor maybe used singly or as a mixture of two or more members thereof, but it is preferable to use one or more members of mercaptan hydrogen donors and one or more members of amine hydrogen donors in combination from the viewpoint of being able to further improve the sensitivity.

In addition, specific examples of the triazine compound may include the compounds described in JP 57-6096 B and the paragraphs [0063] to [0065] of JP 2003-238898 A.

In the present invention, in the case of using a photopolymerization initiator other than a biimidazole compound such as an acetophenone compound, it is possible to concurrently use a sensitizer. Examples of such a sensitizer may include 4,4′-bis(dimethylamino)benzophenone, 4,4′-bis(diethylamino)benzophenone, 4-diethylaminoacetophenone, 4-dimethylaminopropiophenone, ethyl 4-dimethylaminobenzoate, 2-ethylhexyl 4-dimethylaminobenzoate, 2,5-bis(4-diethylaminobenzal)cyclohexanone, 7-diethylamino-3-(4-diethylaminobenzoyl)coumarin, and 4-(diethylamino)chalcone.

In the present invention, the content of (E) the photopolymerization initiator is preferably from 0.1 to 120 parts by mass, more preferably from 1 to 100 parts by mass, and even more preferably from 5 to 70 parts by mass with respect to 100 parts by mass of (D) the polymerizable compound. By having such an aspect, the curability and coating film properties are further enhanced, and tinting strength can be even further improved.

### (F) Solvent

The coloring composition of the present invention contains (G) at least one member selected from the group consisting of an alcohol, a ketone, and an alkyl lactate as (F) a solvent. This makes it possible to obtain a coloring composition which exhibits excellent film thickness uniformity and patterning property.

The component (G) can be classified into (F1) an alcohol, a ketone, and an alkyl lactate which have a boiling point of lower than 180° C. at 1 atm and (F4) an alcohol, a ketone, and an alkyl lactate which have of 180° C. or higher at 1 atm. Here, the boiling point of the component (F1) at 1 atm is preferably 100° C. or higher and lower than 180° C. and even more preferably 110° C. or higher and 170° C. or lower. Meanwhile, the boiling point of the component (F4) at 1 atm is preferably 180° C. or higher and 250° C. or lower, more preferably 180° C. or higher and 230° C. or lower, even more preferably 190° C. or higher and 220° C. or lower, and even more preferably 200° C. or higher and 220° C. or lower.

The component (F1) is not particularly limited as long as it is an alcohol, ketone, or alkyl lactate having a boiling point of lower than 180° C. at 1 atm, but examples thereof may include a (poly)alkylene glycol monoalkyl ether such as ethylene glycol monoethyl ether (boiling point: 124° C., the same applies hereinafter), ethylene glycol monoethyl ether (135° C.), ethylene glycol mono-n-propyl ether (150° C.), ethylene glycol mono-n-butyl ether (171° C.), propylene glycol monomethyl ether (120° C.), propylene glycol monoethyl ether (133° C.), propylene glycol mono-n-propyl ether (150° C.) or propylene glycol mono-n-butyl ether (170° C.) ;

a (cyclo)alkyl alcohol such as methanol (65° C.), ethanol (78° C.), propanol (97° C.), 1-butanol (117° C.), isopropanol (82° C.), isobutanol (108° C.), t-butanol (82° C.), 3-methoxy-1-butanol (161° C.), or cyclohexanol (161° C.) ;

an alkyl lactate such as methyl lactate (144° C.) or ethyl lactate (153° C.) ;

a keto alcohol such as diacetone alcohol (166° C.); and

a ketone such as methyl ethyl ketone (80° C.), cyclohexanone (156° C.), 2-heptanone (151° C.), or 3-heptanone (149° C.)

The component (F1) may be used singly or as a mixture of two or more members thereof.

In addition, the component (F4) is not particularly limited as long as it is an alcohol, ketone, or alkyl lactate having a boiling point of 180° C. or higher at 1 atm, but examples thereof may include a (poly)alkylene glycol monoalkyl ether such as diethylene glycol monomethyl ether (194° C.), diethylene glycol monoethyl ether (202° C.), diethylene glycol mono-n-butyl ether (231° C.), triethylene glycol monomethyl ether (249° C.), triethylene glycol monoethyl ether (256° C.), dipropylene glycol monomethyl ether (190° C.), dipropylene glycol mono-n-propyl ether (212° C.), dipropylene glycol mono-n-butyl ether (229° C.), tripropylene glycol monomethyl ether (242° C.), or tripropylene glycol n-butyl ether (274° C.);

a glycol such as 1,3-butylene glycol (208° C.); and

a (cyclo)alkyl alcohol such as octanol (195° C.) or 2-ethylhexanol (184° C.)

The component (F4) may be used singly or as a mixture of two or more members thereof.

Among them, as the component (G), the component (F1) is preferable and an alcohol is more preferable. Among the alcohols, ethylene glycol mono-n-butyl ether, dipropylene glycol mono-n-propyl ether, dipropylene glycol monomethyl ether, propylene glycol mono-n-butyl ether, propylene glycol monomethyl ether, propylene glycol monoethyl ether, propylene glycol mono-n-propyl ether, diethylene glycol monoethyl ether, ethanol, 3-methoxybutanol, and diacetone alcohol are preferable.

In addition, the coloring composition of the present invention may contain a solvent other than the component (G). Examples of such a solvent may include (F2) a solvent other than the alcohol, ketone, and alkyl lactate which have a boiling point of 180° C. or higher at 1 atm and (F3) a solvent other than the alcohol, ketone, and alkyl lactate which have a boiling point of lower than 180° C. at 1 atm. Here, the boiling point of the component (F2) at 1 atm is preferably 180° C. or higher and 250° C. or lower, more preferably 180° C. or higher and 230° C. or lower, even more preferably 190° C. or higher and 220° C. or lower, and even more preferably 200° C. or higher and 220° C. or lower. Meanwhile, the boiling point of the component (F3) at 1 atm is preferably 100° C. or higher and lower than 180° C., more preferably 130° C. or higher and 175° C. or lower, and even more preferably 150° C. or higher and 175° C. or lower.

The component (F2) is not particularly limited as long as it is a solvent other than the alcohol, ketone, and alkyl lactate which have a boiling point of 180° C. or higher at 1 atm, but examples thereof may include an ester such as dipropylene glycol methyl ether acetate (213° C.), propylene glycol diacetate (190° C.), 1,3-butylene glycol diacetate (232° C.), 1,6-hexanediol diacetate (260° C.), ethylene glycol monobutyl ether acetate (192° C.), diethylene glycol monoethyl ether (202° C.), diethylene glycol monoethyl ether acetate (217° C.), diethylene glycol monobutyl ether acetate (245° C.), or triacetin (260° C.)

a cyclic ester such as γ-butyrolactone (204° C.); and

a lactam such as N-methylpyrrolidone (202° C.).

The component (F2) may be used singly or as a mixture of two or more members thereof.

Among them, as the component (F2), dipropylene glycol methyl ether acetate, propylene glycol diacetate, 1,3-butylene glycol diacetate, diethylene glycol monoethyl ether acetate, and γ-butyrolactone are preferable, and particularly dipropylene glycol methyl ether acetate, diethylene glycol monoethyl ether acetate, and γ-butyrolactone are more preferable.

The component (F3) is not particularly limited as long as it is a solvent other than the alcohol, ketone, and alkyl lactate which have a boiling point of lower than 180° C. at 1 atm, but examples thereof may include an ester such as ethylene glycol monomethyl ether acetate (145° C.), propylene glycol monomethyl ether acetate (146° C.), propylene glycol monoethyl ether acetate (160° C.), 3-methoxybutyl acetate (171° C.), diethylene glycol dimethyl ether (162° C.), diethylene glycol methyl ethyl ether (179° C.), methyl 3-methoxypropionate (143° C.), ethyl 3-methoxypropionate (158° C.), methyl 3-ethoxypropionate (167° C.), ethyl 3-ethoxypropionate (170° C.), tetrahydrofuran (66° C.), n-butyl acetate (126° C.), i-butyl acetate (118° C.), n-butyl propionate (146° C.), ethyl butyrate (121° C.), i-propyl butyrate (131° C.), n-butyl butyrate (165° C.), or ethyl pyruvate (144° C.);

an aromatic hydrocarbon such as toluene (111° C.) or xylene (139° C.) ; and

an amide such as N,N-dimethylformamide (153° C.) or N,N-dimethylacetamide (165° C.)

The component (F3) may be used singly or as a mixture of two or more members thereof.

Among them, it is particularly preferable to contain at least one member selected from the group consisting of propylene glycol monoethyl ether acetate, 3-methoxybutyl acetate, and ethyl 3-ethoxypropionate as the component (F3) from the viewpoint of solubility and pigment dispersibility, for example.

The content of (F) the solvent is not particularly limited, but it is preferably an amount so that the total concentration of the respective components in the coloring composition excluding the solvent becomes from 5 to 50 mass % and it is more preferably an amount so that the total concentration becomes from 10 to 40 mass %. By having such an aspect, it is possible to obtain a colorant dispersion which exhibits favorable dispersibility and stability and a coloring composition which exhibits favorable coatability and stability.

The proportion of the component (G) contained is preferably from 3 to 40 mass %, more preferably from 5 to 35 mass %, even more preferably from 7 to 30 mass %, and even more preferably from 10 to 25 mass % in the total amount of solvent.

In addition, the proportion of the solvent having a high boiling point of 180° C. or higher at 1 atm, namely, the component (F2) and the component (F4) contained is preferably from 1 to 40 mass %, more preferably from 3 to 40 mass %, even more preferably from 5 to 35 mass %, and even more preferably from 10 to 30 mass % in the total amount of solvent.

Furthermore, the proportion of the component (F3) contained is preferably from 10 to 97 mass %, more preferably from 20 to 90 mass %, even more preferably from 30 to 80 mass %, even more preferably from 40 to 70 mass %, and even more preferably from 45 to 60 mass % in the total amount of solvent.

### Additive

The coloring composition of the present invention may contain various additives if necessary.

Examples of the additive may include a filler such as glass or alumina; a polymer compound such as polyvinyl alcohol or poly (fluoroalkyl acrylate); a surfactant such as a fluorine surfactant or a silicon surfactant; an adhesion promoter such as vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloyloxypropyltrimethoxysilane, or 3-mercaptopropyltrimethoxysilane; an antioxidant such as 2,2-thiobis(4-methyl-6-t-butylphenol), 2,6-di-t-butylphenol, pentaerythritol tetrakis[3-(3,5-di-t-butyl-4-hydroxyphenyl) propionate], 3,9-bis[2-[3-(3-t-butyl-4-hydroxy-5-methylphenyl)-propionyloxy]-1,1-dimethylethyl]-2,4,8,10-tetraoxa-spiro[5.5]undecane, or thiodiethylenebis[3-(3,5-di-t-butyl-4-hydroxyphenyl)propionate]; an ultraviolet absorber such as 2-(3-t-butyl-5-methyl-2-hydroxyphenyl)-5-chlorobenzotriazole or alkoxybenzophenone, an aggregation inhibitor such as sodium polyacrylate; a residue improving agent such as malonic acid, adipic acid, itaconic acid, citraconic acid, fumaric acid, mesaconic acid, 2-aminoethanol, 3-amino-1-propanol, 5-amino-1-pentanol, 3-amino-1,2-propanediol, 2-amino-1,3-propanediol, or 4-amino-1,2-butanediol; and a developability improving agent such as mono[2-(meth)acryloyloxyethyl] succinate, mono[2-(meth)acryloyloxyethyl] phthalate, or w-carboxypolycaprolactone mono(meth)acrylate.

The coloring composition of the present invention can be prepared by a suitable method, and as the preparation method therefor, for example, the coloring composition can be prepared by mixing (A) the colorant containing (A1) the pigment X and (A2) the isoindoline pigment, (C) the binder resin, and (D) the polymerizable compound together with (F) the solvent containing the component (G) and other components to be arbitrarily added.

As a more specific method for preparing the coloring composition, for example, it is possible to employ a method in which a first colorant dispersion which contains (A) the colorant containing (A1) the pigment X, (B) the dispersant, (F) the solvent containing the component (G), and a part of (C) the binder resin as an arbitrary component and a second colorant dispersion which contains (A) the colorant containing (A2) the isoindoline pigment, (B) the dispersant, (F) the solvent containing the component (G), and a part of (C) the binder resin as an arbitrary component are prepared respectively, and the first colorant dispersion, the second colorant dispersion, and (D) the polymerizable compound, and if necessary, (C) the binder resin, (E) the photopolymerization initiator, and an additional amount of (F) the solvent, and other components are added and mixed together to prepare the coloring composition (hereinafter, also referred to as the “preparation method (1)”). Alternatively, it is possible to employ a method in which a colorant dispersion which contains (A) the colorant containing (A1) the pigment X and (A2) the isoindoline pigment, (B) the dispersant, (F) the solvent containing the component (G), and a part of (C) the binder resin as an arbitrary component is prepared, and the colorant dispersion, and (D) the polymerizable compound, and if necessary, (C) the binder resin, (E) the photopolymerization initiator, and an additional amount of (F) the solvent, and other components are added and mixed together to prepare the coloring composition (hereinafter, also referred to as the “preparation method (2)”).

Between these, the preparation method (2) is preferable from the viewpoint of obtaining a coloring composition which exhibits excellent dispersion stability of the pigment.

In the preparation methods (1) and (2), a suitable aspect of the component (G) contained in the colorant dispersion is the same as the suitable aspect of the component (G) described in the coloring composition of the present invention.

### Colored Cured Film and Method for Producing the Same

The colored cured film of the present invention contains (A1) the pigment X and (A2) the isoindoline pigment, satisfies any one or more of the following conditions (1) to (4) at a film thickness of 0.5 μm, and can be formed by using the coloring composition of the present invention.

(1) The transmittance at a wavelength of 400 nm is 30% or less.

(2) The maximum transmittance in a wavelength region of from 430 to 560 nm is 15% or less.

(3) The transmittance at a wavelength of 580 nm is 50% or less.

(4) The transmittance at a wavelength of 620 nm is 80% or more.

The colored cured film of the present invention can be formed into a red cured film which hardly affects the transmissive region of the green cured film as it satisfies at least one selected from the conditions (1) and (2). In the condition (1), the transmittance at a wavelength of 400 nm is more preferably 2 5% or less and even more preferably 20% or less from the viewpoint of efficiently shielding light in violet to blue. In the condition (2), the maximum transmittance in a wavelength region of from 430 to 560 nm is more preferably 13% or less, even more preferably 12% or less, and even more preferably 10% or less from the viewpoint of efficiently shielding light in blue to green.

The colored cured film of the present invention can be formed into a red cured film which exhibits excellent color separation property between the red cured film and the green cured film as it satisfies the condition (3). In the condition (3), the transmittance at a wavelength of 580 nm is more preferably 40% or less and even more preferably 30% or less from the viewpoint of color reproducibility.

The colored cured film of the present invention can be formed into a red cured film which exhibits excellent light sensitivity as it satisfies the condition (4). In the condition (4), the transmittance at a wavelength of 620 nm is more preferably 83% or more and even more preferably 85% or more from the viewpoint of color reproducibility.

The red cured film more preferably satisfies any two or more of the conditions (1) to (4), even more preferably satisfies any three or more of the conditions (1) to (4), and even more preferably satisfies all of the conditions (1) to (4) although it depends on the properties to be required.

Hereinafter, a colored cured film to be used in a color filter and a method for forming the colored cured film will be described.

Examples of the method for forming the colored cured film constituting a color filter may first include the following method. First, a light-shielding layer (black matrix) is formed on the surface of a substrate so as to partition the part on which a pixel is formed, if necessary. Subsequently, for example, a liquid composition of the red radiation-sensitive coloring composition of the present invention is applied on this substrate, and the solvent is evaporated through prebaking to form a coating film. Subsequently, this coating film is exposed to light via a photomask and developed with an alkali developing solution to dissolve and remove the unexposed portion of the coating film. Thereafter, post-baking is conducted, whereby a pixel array in which a red pixel pattern (colored cured film) is disposed in a predetermined arrangement is formed.

Subsequently, coating, prebaking, exposure, development, and post-baking of each radiation-sensitive coloring composition is conducted in the same manner as above by using each radiation-sensitive coloring composition in green or blue, whereby a green pixel array and a blue pixel array are sequentially formed on the same substrate. A color filter in which pixel arrays in three primary colors of red, green, and blue are disposed on a substrate is thus obtained. However, in the present invention, the order to form the pixels in the respective colors is not limited to the above order.

In addition, the black matrix can be formed by forming a metal thin film, for example, of chromium deposited by sputtering or vapor deposition into a desired pattern by utilizing a photolithographic method, but the black matrix can also be formed in the same manner as in the case of forming the pixels described above by using a radiation-sensitive coloring composition in which a black pigment is dispersed.

Examples of the substrate to be used when forming a colored cured film may include glass, silicon, polycarbonate, polyester, aromatic polyamide, polyamideimide, and polyimide.

In addition, these substrates may be subjected to appropriate pretreatments such as a chemical treatment, for example, with a silane coupling agent, a plasma treatment, ion plating, sputtering, a gas phase reaction method, and vacuum vapor deposition if desired.

It is possible to employ an appropriate coating method such as a spraying method, a roll coating method, a spin coating method (spin coating method), a slit die coating method (slit coating method), or a bar coating method when applying the radiation-sensitive coloring composition on a substrate, but it is preferable to employ a spin coating method or a slit die coating method in particular.

Pre-baking is usually conducted by combining vacuum drying and drying by heating. The vacuum drying is usually conducted until the pressure reaches 50 to 200 Pa. The conditions for drying by heating are usually for about 1 to 10 minutes at from 70 to 110° C.

The coating thickness is generally from 0.3 to 5 μm as the film thickness after drying.

Examples of the light source of radiation to be used when forming at least one member selected from a pixel and a black matrix may include a lamp light source such as a xenon lamp, a halogen lamp, a tungsten lamp, a high pressure mercury lamp, an ultrahigh pressure mercury lamp, a metal halide lamp, a medium pressure mercury lamp, a low pressure mercury lamp and a laser light source such as an argon ion laser, a YAG laser, a XeCl excimer laser, or a nitrogen laser. As a light source for exposure, an ultraviolet LED can also be used. Radiation having a wavelength in a range of from 190 to 450 nm is preferable.

The exposure value to radiation is generally preferably from 10 to 10,000 J/m².

In addition, as the alkali developing solution, an aqueous solution, for example, of sodium carbonate, sodium hydrogen carbonate, sodium hydroxide, potassium hydroxide, tetramethylammonium hydroxide, choline, 1,8-diazabicyclo-[5.4.0]-7-undecene, or 1,5-diazabicyclo-[4.3.0]-5-nonene is preferable.

It is also possible to add a suitable amount of a water-soluble organic solvent such as methanol or ethanol or a surfactant to the alkaline developing solution, for example. The alkaline developing solution is usually washed with water after alkali development.

As the developing treatment method, for example, a shower development method, a spray development method, a dipping (immersion) development method, and a puddle development method can be applied. The developing conditions are preferably for from 5 to 300 seconds at room temperature.

The conditions for post-baking are usually for about from 3 to 60 minutes at from 180 to 280° C.

The film thickness of the pixel thus formed is usually from 0.5 to 5 μm and preferably from 1.0 to 3 μm.

In addition, as a second method for forming a colored cured film constituting a color filter, it is possible to employ the method which is disclosed, for example, in JP 7-318723 A and JP 2000-310706 A and in which pixels in the respective colors are obtained by an inkjet method. In this method, first, a partition wall which also has a light shielding function is formed on the surface of a substrate. Subsequently, for example, a liquid composition of the red thermosetting coloring composition of the present invention is ejected into the partition wall thus formed by using an ink jet apparatus, and the solvent is then evaporated through prebaking. Subsequently, this coating film is exposed to light if necessary and then cured through post-baking, whereby a red pixel pattern is formed.

Subsequently, a green pixel pattern and a blue pixel pattern are sequentially formed on the same substrate in the same manner as above by using each thermosetting coloring composition in green or blue. A color filter in which pixel arrays in three primary colors of red, green, and blue are disposed on a substrate is thus obtained. However, in the present invention, the order to form the pixels in the respective colors is not limited to the above order.

The partition wall not only functions to shield light but also functions to prevent mixing of the thermosetting coloring compositions in the respective colors ejected into the partition, and film thickness is thus thicker as compared to the black matrix to be used in the first method described above. Hence, the partition wall is usually formed by using a black radiation-sensitive composition.

The substrate and light source of radiation to be used when forming the colored cured film and the method and conditions for prebaking and post-baking are the same as those in the first method described above. The film thickness of the pixel to be thus formed by the inkjet method is about the same as the height of the partition wall.

It is also possible to form a protective film on the pixel pattern thus obtained if necessary.

The color filter that is thus formed and includes the colored cured film of the present invention is suitable for the formation of a red pixel which exhibits favorable color reproducibility and hardly affects the transmissive region of the green pixel, and it is thus extremely useful, for example, in a solid-state imaging element such as a CMOS image sensor, a color imaging tube element, and a color sensor, and it is especially useful as a red pixel of a color filter for solid-state imaging element.

The colored cured film of the present invention can be suitably used as a red pixel which exhibits favorable color reproducibility and hardly affects the transmissive region of the green pixel although the film thickness thereof is from 0.4 to 0.8 μm, further from 0.4 to 0.6 μm, and particularly from 0.45 to 0.55 μm.

### Solid-State Imaging Element

The solid-state imaging element of the present invention is equipped with the colored cured film of the present invention. Especially, the red pixel formed by using the coloring composition of the present invention is suitable for a color filter of a solid-state imaging element since it exhibits favorable color reproducibility and hardly affects the transmissive region of the green pixel. In addition, the solid-state imaging element of the present invention can adopt an appropriate structure. For example, as one embodiment, it is possible to fabricate a solid-state imaging element which exhibits particularly excellent spectral properties and color separation property by forming a colored pixel (colored cured film) on a semiconductor substrate such as a CMOS substrate by using the coloring composition of the present invention through the same operation as described above.

In addition, as a suitable aspect of the color filter of the solid-state imaging element of the present invention, it is preferable that a red pixel, a blue pixel, and a green pixel are the following ones.

### Red Pixel

It is preferable that the red pixel contains (A1) the pigment X and (A2) the isoindoline pigment and satisfies any one or more of the above conditions (1) to (4) at a film thickness of 0.5 μm from the viewpoint of forming a red pixel which exhibits favorable color reproducibility and hardly affects the transmissive region of the green pixel. In addition, the film thickness thereof is preferably 0.7 μm or less, more preferably 0.6 μm or less, even more preferably 0.55 μm or less, and even more preferably 0.5 μm or less as the condition (5) from the viewpoint of satisfying the requirement for thinning of the film in recent years.

The red pixel more preferably satisfies any two or more of the conditions (1) to (4), even more preferably satisfies any three or more of the conditions (1) to (4), and even more preferably satisfies all of the conditions (1) to (4) although it depends on the properties to be required.

Among the conditions (1) to (4), it is preferable to satisfy at least the condition (4), it is more preferable to satisfy at least the conditions (2) and (4), it is even more preferable to satisfy at least the conditions (2), (3), and (4), and it is even more preferable to satisfy all of the conditions (1) to (4).

It is preferable to satisfy these preferred aspects on the conditions (1) to (4) and the aspect on the condition (5) at the same time.

The proportion of (A1) the pigment X and (A2) the isoindoline pigment contained can be appropriately set, but it is preferably from 85/15 to 65/35 as the mass ratio [(A1)/(A2)] of (A1) the pigment X to (A2) the isoindoline pigment from the viewpoint of forming a red pixel which exhibits favorable color reproducibility and hardly affects the transmissive region of the green pixel.

The mass ratio [(A1)/(A2)] is preferably from 80/20 to 65/35, more preferably from 75/25 to 65/35, and even more preferably from 70/30 to 65/35 from the viewpoint of even further decreasing the transmittance at a wavelength of 400 nm. Such an aspect makes it possible to form a red pixel which satisfies the condition (1).

The mass ratio [(A1)/(A2)] is preferably from 85/15 to 70/30, more preferably from 85/15 to 75/25, and even more preferably from 85/15 to 80/20 from the viewpoint of even further decreasing the maximum transmittance in a wavelength region of from 430 to 560 nm. Such an aspect makes it possible to form a red pixel which satisfies the condition (2).

The mass ratio [(A1)/(A2)] is preferably from 85/15 to 70/30 and more preferably from 80/20 to 70/30 from the viewpoint of decreasing the transmittance at a wavelength of 400 nm and the maximum transmittance in a wavelength region of from 430 to 560 nm in a favorable balance. Such an aspect makes it possible to form a red pixel which satisfies the conditions (1) and (2).

### Green Pixel

The green pixel contains preferably C.I. Pigment Green 36, C.I. Pigment Green 58, or C.I. Pigment Green 59 and more preferably C.I. Pigment Green 58 or C.I. Pigment Green 59 as a colorant from the viewpoint of forming a green pixel which exhibits favorable color reproducibility in spite of a thin film and hardly affects the transmissive regions of the blue pixel and the red pixel.

The green pixel may contain another colorant other than the green colorant, and it is even more preferable to contain a yellow colorant. As the yellow colorant, C.I. Pigment Yellow 138, C.I. Pigment Yellow 139, C.I. Pigment Yellow 150, and C.I. Pigment Yellow 185 are preferable and C.I. Pigment Yellow 185 is more preferable from the viewpoint of forming a green pixel which exhibits favorable color reproducibility in spite of a thin film and hardly affects the transmissive regions of the blue pixel and the red pixel.

In the green coloring composition to be used for the formation of the green pixel, the proportion of the colorant contained is usually from 5 to 70 mass %, preferably from 15 to 60 mass %, more preferably from 30 to 55 mass %, and even more preferably from 35 to 50 mass % in the solids of the green coloring composition from the viewpoint of forming a green pixel which exhibits favorable color reproducibility and hardly affects the transmissive regions of the blue pixel and the red pixel.

### Blue Pixel

The blue pixel preferably contains C.I. Pigment Blue 15:6 or C.I. Pigment Violet 23 as a colorant from the viewpoint of forming a blue pixel which exhibits favorable color reproducibility in spite of a thin film and hardly affects the transmissive region of the green pixel.

In the blue coloring composition to be used for the formation of the blue pixel, the proportion of the colorant contained is usually from 5 to 70 mass %, preferably from 15 to 60 mass %, more preferably from 30 to 55 mass %, and even more preferably from 35 to 50 mass % in the solids of the blue coloring composition from the viewpoint of forming a blue pixel which exhibits favorable color reproducibility and hardly affects the transmissive region of the green pixel.

### EXAMPLES

Hereinafter, the embodiments of the present invention will be described in more detail with reference to Examples. However, the present invention is not limited to the following Examples.

### <Synthesis of Binder Resin>

### Synthesis Example 1

Into a flask equipped with a cooling tube and a stirrer, 100 parts by mass of propylene glycol monomethyl ether acetate was introduced, and the flask was purged with nitrogen. The flask was heated to 80° C., and a mixed solution of 100 parts by mass of propylene glycol monomethyl ether acetate, 25 parts by mass of benzyl methacrylate, 10 parts by mass of styrene, 20 parts by mass of N-phenyl maleimide, 5 parts by mass of glycerol monomethacrylate, 10 parts by mass of methacrylic acid, 30 parts by mass of ω-carboxypolycaprolactone monoacrylate, and 3 parts by mass of 2,2-azobisisobutyronitrile was added thereto dropwise over 1 hour at the same temperature, and the polymerization thereof was conducted for 3 hours by maintaining this temperature. Thereafter, the temperature of the reaction mixture was raised to 100° C., and the polymerization thereof was further conducted for 1 hour, thereby obtaining a binder resin solution (solids concentration: 40 mass %). The binder resin thus obtained had Mw of 9,800 and Mn of 6,000. This binder resin solution is referred to as the “binder resin (C-1) solution”.

### Synthesis Example 2

Into a flask equipped with a cooling tube and a stirrer, 3 parts by mass of 2,2′-azobisisobutyronitrile and 100 parts by mass of propylene glycol monomethyl ether acetate were introduced, subsequently 12 parts by mass of N-phenylmaleimide, 10 parts by mass of styrene, 20 parts by mass of methacrylic acid, 15 parts by mass of 2-hydroxyethyl methacrylate, 29 parts by mass of 2-ethylhexyl methacrylate, 14 parts by mass of benzyl methacrylate, and 5 parts by mass of pentaerythritol tetrakis (3-mercaptopropionate) (manufactured by SAKAI CHEMICAL INDUSTRY CO., LTD.) were introduced thereinto, and the flask was purged with nitrogen. Thereafter, the reaction solution was gently stirred, the temperature thereof was raised to 80° C., and the polymerization thereof was conducted for 3 hours by maintaining this temperature. Thereafter, the temperature of the reaction solution was raised to 100° C., and the polymerization thereof was further conducted for 1 hour.

After the resultant was cooled to room temperature, propylene glycol monomethyl ether acetate was added thereto so that the solids concentration thereof was 40 mass %, thereby obtaining a binder resin solution (solids concentration: 40 mass %). The binder resin thus obtained had Mw of 9,700 and Mn of 5,700. This binder resin solution is referred to as the “binder resin (C-2) solution”.

### Synthesis Example 3

Into a reaction vessel, 370 parts by mass of propylene glycol monomethyl ether acetate was introduced and heated to 80° C. while injecting nitrogen gas into the vessel, and a mixture of the following monomers and a thermal polymerization initiator were added thereto dropwise over 1 hour at the same temperature, and the polymerization reaction thereof was conducted.

Methacrylic acid: 20.0 parts by mass

Methyl methacrylate: 10.0 parts by mass

n-Butyl methacrylate: 35.0 parts by mass

2-Hydroxyethyl methacrylate: 15.0 parts by mass

2,2′-azobisisobutyronitrile: 4.0 parts by mass

p-cumylphenolethylene oxide-modified acrylate: 20.0 parts by mass (“ARONIX M110” manufactured by TOAGOSEI CO., LTD.)

After the dropwise addition of the mixture was completed, the reaction mixture was further reacted for 3 hours at 80° C., a solution obtained by dissolving 1.0 part by mass of azobisisobutyronitrile in 50 parts by mass of propylene glycol monomethyl ether acetate was then added thereto, and the reaction was continuously conducted for 1 hour at 80° C., thereby obtaining a solution of a binder resin.

After the resultant was cooled to room temperature, the solids concentration thereof was adjusted to 40 mass % through vacuum concentration. The binder resin thus obtained had Mw of 40,000. This binder resin solution is referred to as the “binder resin (C-3) solution”.

### Synthesis Example 4

Into a 1 L flask equipped with a reflux condenser, a dropping funnel, and a stirrer, a proper amount of nitrogen was allowed to flow to obtain a nitrogen atmosphere, and 100 parts by mass of propylene glycol monomethyl ether acetate was introduced into the flask and heated to 85° C. while stirring. Subsequently, a solution obtained by dissolving 19 parts by mass of methacrylic acid and 171 parts by mass of 3,4-epoxytricyclo[5.2.1.0^{2.6}]decyl acrylate (a mixture of a compound represented by Formula (I-1) and a compound represented by Formula (II-1), molar ratio=50:50) in 40 parts by mass of propylene glycol monomethyl ether acetate was added dropwise into the flask over about 5 hours by using a dropping pump. Meanwhile, a solution obtained by dissolving 26 parts by mass of 2,2′-azobis(2,4-dimethylvaleronitrile) of a polymerization initiator in 120 parts by mass of propylene glycol monomethyl ether acetate was added dropwise into the flask over about 5 hours by using a separate dropping pump. After the dropwise addition of the polymerization initiator was completed, the reaction system was maintained at the same temperature for about 3 hours.

After the resultant was cooled to room temperature, propylene glycol monomethyl ether acetate was added thereto so that the solids concentration thereof was 40 mass %, thereby obtaining a binder resin solution (solids concentration: 40 mass %). The binder resin thus obtained had Mw of 8,000 and Mw/Mn of 2.0. This binder resin solution is referred to as the “binder resin (C-4) solution”.

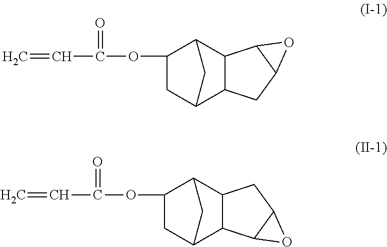 [SMILES: C=CC(=O)OC1CC2CC1C1C2CC2OC21 ; C=CC(=O)OC1CC2CC1C1CC3OC3C21]

### <Synthesis of Binder Resin Having Polymerizable Unsaturated Group>

### Synthesis Example 5

Into a flask equipped with a cooling tube and a stirrer, 90 parts by mass of propylene glycol monomethyl ether acetate was introduced, and the flask was purged with nitrogen and then heated to 90° C. To this, a mixed solution of 50 parts by mass of propylene glycol monomethyl ether acetate, 12 parts by mass of N-phenyl maleimide, 10 parts by mass of styrene, 38 parts by mass of 2-ethylhexyl ethylene oxide-modified acrylate (ARONIX M120 manufactured by TOAGOSEI CO., LTD.), 10 parts by mass of 2-hydroxyethyl methacrylate, 30 parts by mass of methacrylic acid, and 2 parts by mass of mercaptopropionic acid and a mixed solution of 5 parts by mass of 2,2′-azobisbutyronitrile and 60 parts by mass of propylene glycol monomethyl ether acetate were respectively added dropwise over 2 hours. Thereafter, the polymerization thereof was conducted for 1 hour by maintaining this temperature. Next, 16.5 parts by mass of glycidyl methacrylate, 1.15 parts by mass of tetrabutylammonium bromide, and 0.34 part by mass of 4-methoxyphenol were introduced into the flask, and the addition reaction thereof was conducted for 5 hours at 110° C.

After the resultant was cooled to room temperature, propylene glycol monomethyl ether acetate was added thereto so that the solids concentration thereof was 40 mass %, thereby obtaining a binder resin solution (solids concentration: 40 mass %). The binder resin thus obtained had Mw of 11,600 and Mn of 4,800. This binder resin solution is referred to as the “binder resin (C-5) solution”.

### Synthesis Example 6

Into a flask equipped with a cooling tube and a stirrer, 370 parts by mass of propylene glycol monomethyl ether acetate was introduced, the temperature thereof was raised to 80° C., and the inside of the flask was purged with nitrogen. To this, a mixture of 18 parts by mass of p-cumylphenolethylene oxide-modified acrylate (ARONIX M110 manufactured by TOAGOSEI CO., LTD.), 10 parts by mass of benzyl methacrylate, 18.2 parts by mass of glycidyl methacrylate, 25 parts by mass of methyl methacrylate, and 2.0 parts by mass of 2,2′-azobisisobutyronitrile was added dropwise over 2 hours. After the dropwise addition, the mixture was further reacted for 3 hours at 100° C., a solution obtained by dissolving 1.0 parts by mass of azobisisobutyronitrile in 50 parts by mass of propylene glycol monomethyl ether acetate was then added to the resultant, and the mixture was continuously reacted for 1 hour at 100° C. Next, the inside of the vessel was purged with air, 0.5 part by mass of tris(dimethylamino)phenol and 0.1 part by mass of hydroquinone in addition to 9.3 parts by mass (equivalent amount of glycidyl group) of acrylic acid were added into the vessel, and the temperature thereof was raised to 120° C., and the reaction of the mixture was conducted until the acid value of solids reached 0.5. Furthermore, 19.5 parts by mass of tetrahydrophthalic anhydride (equivalent amount of hydroxyl group produced) and 0.5 part by mass of triethylamine were added to the resultant, and the reaction of the mixture was conducted for 3.5 hours at 120° C.

After the resultant was cooled to room temperature, the solids concentration thereof was adjusted to 40 mass % through vacuum concentration. The binder resin thus obtained had Mw of 19,000. This binder resin solution is referred to as the “binder resin (C-6) solution”.

### Synthesis Example 7

Into a reaction vessel, 560 parts by mass of propylene glycol monomethyl ether acetate was introduced and heated to 80° C. while injecting nitrogen gas into the vessel, and a mixture of the following monomers and a thermal polymerization initiator was added thereto dropwise over 1 hour at the same temperature, and the polymerization reaction thereof was conducted.

Methacrylic acid: 34.0 parts by mass

Methyl methacrylate: 23.0 parts by mass

n-Butyl methacrylate: 45.0 parts by mass

2-Hydroxyethyl methacrylate: 70.5 parts by mass

2,2’-azobisisobutyronitrile: 8.0 parts by mass

After the dropwise addition of the mixture was completed, the reaction mixture was further reacted for 3 hours at 100° C., a solution obtained by dissolving 1.0 parts by mass of azobisisobutyronitrile in 55 parts by mass of propylene glycol monomethyl ether acetate was then added to the resultant, and the reaction of the mixture was continuously conducted for 1 hour at 80° C., thereby obtaining a copolymer solution.

Next, a mixture of the following compounds was added dropwise to 338 parts by mass of the copolymer solution thus obtained over 3 hours at 70° C.

2-Methacryloyl ethyl isocyanate: 32.0 parts by mass

Dibutyltin laurate: 0.4 part by mass

Cyclohexanone: 120.0 parts by mass

After the resultant was cooled to room temperature, the solids concentration thereof was adjusted to 40 mass % through vacuum concentration. The binder resin thus obtained had Mw of 20,000. This binder resin solution is referred to as the “binder resin (C-7) solution”.

### Synthesis Example 8

Into a flask equipped with a stirrer, a dropping funnel, a condenser, a thermometer, and a gas introduction tube, 67 parts by mass of propylene glycol monomethyl ether acetate and 33 parts by mass of propylene glycol monomethyl ether were introduced and stirred while purging with nitrogen, and the temperature thereof was raised to 120° C. Next, 1 part by mass of Perbutyl O was added to 100 parts by mass of a monomer mixture consisting of 11 parts by mass of tricyclodecanyl methacrylate, 31 parts by mass of benzyl methacrylate, and 23 parts by mass of methacrylic acid. This was added dropwise into the flask over 2 hours through the dropping funnel, and the mixture was further stirred for 2 hours at 120° C., thereby obtaining a copolymer. Next, the inside of the flask was purged with air, 10 parts by mass of glycidyl methacrylate, 0.46 part by mass of triphenylphosphine, and 0.08 part by mass of methylhydroquinone were put into the solution of the copolymer thus obtained, and the mixture was continuously reacted at 120° C., and the reaction was terminated when the acid value of solids reached 150 KOH mg/g.

After the resultant was cooled to room temperature, the solids concentration thereof was adjusted to 40 mass % through vacuum concentration. The binder resin thus obtained had Mw of 30,000. This binder resin solution is referred to as the “binder resin (C-8) solution”.

### <Synthesis of Dispersant>

### Synthesis Example 9

With reference to Example 1 in WO 2011/129078 A, a block copolymer (the copolymerization ratio of the respective repeating units was dimethylaminoethyl methacrylate/butyl methacrylate/PME-200/methacrylic acid=22/47/26/5, Mw=10,000) composed of block A having a repeating unit derived from dimethylaminoethyl methacrylate, butyl methacrylate, PME-200 (methoxypolyethylene glycol monomethacrylate, manufactured by NOF CORPORATION, R¹ is an ethylene group, R² and R³ are a methyl group, n 4 in Formula (1)), and block B having a repeating unit derived from methacrylic acid was synthesized. This block copolymer is referred to as the “dispersant (B-1)”.

### <Preparation of Composition for Forming Undercoat Film>

### Preparation Example 1

The inside of the flask was purged with nitrogen, 200 parts by mass of a methyl-3-methoxypropionate solution in which 0.6 part by mass of 2,2′-azobisisobutyronitrile was dissolved was then introduced into the flask. Subsequently, 37.5 parts by mass of tert-butyl methacrylate and 62.5 parts by mass o f glycidyl methacrylate were introduced thereinto, and the mixture was stirred and heated for 6 hours at 70° C. After the resultant was cooled, a resin solution containing a polymer was obtained.

Next, 33.3 parts by mass (containing 10 parts of the polymer) of this resin solution was diluted with 31.9 parts by mass of methyl-3-methoxypropionate and 3.4 parts by mass of propylene glycol monomethyl ether, and 0.3 part by mass of trimellitic acid, 0.5 part by mass of 3-glycidoxypropyltrimethoxysilane, 0.005 part by mass of the “FC-4432” (manufactured by 3M Japan Limited) of a trade name were dissolved in the diluted resin solution, thereby preparing a composition for forming an undercoat film.

### <Preparation of Pigment Dispersion>

### Preparation Example 1

The pigment dispersion (R-1) was prepared by mixing and dispersing 9.9 parts by mass of C.I. Pigment Red 264 having an average particle size of 39 nm and 1.1 parts by mass of C.I. Pigment Yellow 185 having an average particle size of 42 nm as colorants, 0.4 part by mass of the dispersion auxiliary α to be presented below, 8.45 parts by mass of the dispersant (B-1) (solids concentration: 40 mass %) as a dispersant, 4.9 parts by mass of the binder resin (C-1) solution (solids concentration: 40 mass %), and 60.25 parts by mass of propylene glycol monomethyl ether acetate and 15.0 parts by mass of propylene glycol monoethyl ether as solvents by using a bead mill. With regard to the average particle size of the pigment, the length of 100 primary particles of the pigment observed through a transmission electron microscope (“H-7650” manufactured by Hitachi High-Technologies Corporation) was measured and the average value thereof was calculated as the average particle size.

### Preparation Examples 2 to 15

The pigment dispersions (R-2) to (R-15) were prepared by changing the member and amount of the respective components as presented in Table 1 in Preparation Example 1.

TABLE 1

| | | | Prep | Prep | Prep | Prep | Prep | Prep | Prep | Prep | Prep | Prep | Prep | Prep | Prep | Prep | Prep |
|---|---|---|---|---|---|---|---|---|---|---|---|---|---|---|---|---|---|
| | | | Ex. | Ex. | Ex. | Ex. | Ex. | Ex. | Ex. | Ex. | Ex. | Ex. | Ex. | Ex. | Ex. | Ex. | Ex. |
| | | | 1 | 2 | 3 | 4 | 5 | 6 | 7 | 8 | 9 | 10 | 11 | 12 | 13 | 14 | 15 |
| Pigment dispersion | | | R-1 | R-2 | R-3 | R-4 | R-5 | R-6 | R-7 | R-8 | R-9 | R-10 | R-11 | R-12 | R-13 | R-14 | R-15 |
| (A) Colorant | | R254 (11 nm) | | | | | | | | | | | | | | | |
| | | R264 (22 nm) | | | | | | | | | | | | | | | |
| | | R264 (39 nm) | 9.9 | 9.35 | 8.8 | 8.25 | 7.7 | 7.15 | 6.6 | 8.8 | 7.7 | | | | | 8.8 | 8.8 |
| | | R264 (58 nm) | | | | | | | | | | | | | | | |
| | | R264 (83 nm) | | | | | | | | | | | | | | | |
| | | R264 (104 nm) | | | | | | | | | | | | | | | |
| | | R254 (41 nm) | | | | | | | | | | 8.8 | 11 | | | | |
| | | R242 (42 nm) | | | | | | | | | | | | 8.8 | | | |
| | | R177 (38 nm) | | | | | | | | | | | | | 8.8 | | |
| | | Y185 (12 nm) | | | | | | | | | | | | | | | |
| | | Y185 (20 nm) | | | | | | | | | | | | | | | |
| | | Y185 (42 nm) | 1.1 | 1.65 | 2.2 | 2.75 | 3.3 | 3.85 | 4.4 | | | 2.2 | | 2.2 | 2.2 | | |
| | | Y185 (60 nm) | | | | | | | | | | | | | | | |
| | | Y185 (81nm) | | | | | | | | | | | | | | | |
| | | Y185 (103 nm) | | | | | | | | | | | | | | | |
| | | Y139 (40 nm) | | | | | | | | 2.2 | 3.3 | | | | | | |
| | | Y150 (41nm) | | | | | | | | | | | | | | 2.2 | |
| | | Y138 (41nm) | | | | | | | | | | | | | | | 2.2 |
| Dispersion | | α | 0.4 | 0.4 | 0.4 | 0.4 | 0.4 | 04 | 0.4 | 0.4 | 0.4 | 0.4 | 0.4 | 0.4 | 0.4 | 0.4 | 0.4 |
| auxiliary | | β | | | | | | | | | | | | | | | |
| | | γ | | | | | | | | | | | | | | | |
| (B) | (B1) | Dispersant | 8.45 | 8.45 | 8.45 | 8.45 | 8.45 | 8.45 | 8.45 | 8.45 | 8.45 | 8.45 | 8.45 | 8.45 | 8.45 | 8.45 | 8.45 |
| Dispersent | | (B-1) | | | | | | | | | | | | | | | |
| | | LPN19 | | | | | | | | | | | | | | | |
| | | LPN21116 | | | | | | | | | | | | | | | |
| | (B2) | byk2001 | | | | | | | | | | | | | | | |
| (C) Binder | (C1) | C-5 | | | | | | | | | | | | | | | |
| resin | | C-6 | | | | | | | | | | | | | | | |
| | | C-7 | | | | | | | | | | | | | | | |
| | | C-8 | 4.9 | 4.9 | 4.9 | 4.9 | 4.9 | 4.9 | 4.9 | 4.9 | 4.9 | 4.9 | 4.9 | 4.9 | 4.9 | 4.9 | 4.9 |
| | (C2) | C-1 | | | | | | | | | | | | | | | |
| | | C-2 | | | | | | | | | | | | | | | |
| | | C-3 | | | | | | | | | | | | | | | |
| | | C-4 | | | | | | | | | | | | | | | |
| (F) | (F1) | PGME | 15 | 15 | 15 | 15 | 15 | 15 | 15 | 15 | 15 | 15 | 15 | 15 | 15 | 15 | 15 |
| Solvent | | PGEE | | | | | | | | | | | | | | | |
| | | PNP | | | | | | | | | | | | | | | |
| | | DAA | | | | | | | | | | | | | | | |
| | | EL | | | | | | | | | | | | | | | |
| | | CHN | | | | | | | | | | | | | | | |
| | (F2) | γBL | | | | | | | | | | | | | | | |
| | | EDGAC | | | | | | | | | | | | | | | |
| | | DPMA | | | | | | | | | | | | | | | |
| | (F3) | PGMEA | 60.25 | 60.25 | 60.25 | 60.25 | 60.25 | 60.25 | 63.25 | 60.25 | 60.25 | 60.25 | 60.25 | 60.25 | 60.25 | 60.25 | 60.25 |
| | | EEP | | | | | | | | | | | | | | | |
| | | MBA | | | | | | | | | | | | | | | |

In Table 1, the respective components are as follows.

R264: C.I. Pigment Red 264

R254: C.I. Pigment Red 254

R242: C.I. Pigment Red 242

R177: C.I. Pigment Red 177

Y185: C.I. Pigment Yellow 185

Y139: C.I. Pigment Yellow 139

Y150: C.I. Pigment Yellow 150

Y138: C.I. Pigment Yellow 138

However, the numerical value in parentheses after the pigment name indicates the average particle size of the pigment used.

LPN6919: BYK-LPN6919 ((meth)acrylic dispersant manufactured by BYK, solids concentration=60 mass %, the proportion of a repeating unit having an alkylene oxide structure contained in the total repeating units is 11 mass %)

LPN 21116: BYK-LPN 21116 ((meth)acrylic dispersant manufactured by BYK, solids concentration=40 mass %, the proportion of a repeating unit having an alkylene oxide structure contained in the total repeating units is 7 mass %)

byk2001: DISPERBYK-2001 ((meth)acrylic dispersant manufactured by BYK, solids concentration=46)mass %

Dispersion auxiliary α: Compound C3 (quinophthalone-based pigment derivative having a sulfo group) described in the paragraph [0089] of JP 2006-265528 A

Dispersion auxiliary β: Compound 1 (diketopyrrolopyrrole-based pigment derivative having a sulfo group) described in the paragraph [0210] of JP 2011-246649 A

Dispersion auxiliary γ: Compound (D-1) (diketopyrrolopyrrole-based pigment derivative having a carboxyl group) described in the paragraph [0060] of JP 2004-067714 A

PGME: propylene glycol monomethyl ether

PGEE: propylene glycol monoethyl ether

PNP: propylene glycol mono-n-propyl ether

DAA: diacetone alcohol

EL: ethyl lactate

CHN: cyclohexanone

γBL: γ-butyrolactone

EDGAC: diethylene glycol monoethyl ether acetate

DPMA: dipropylene glycol methyl ether acetate

PGMEA: propylene glycol monomethyl ether acetate

EEP: ethyl 3-ethoxypropionate

MBA: 3-methoxybutyl acetate

### <Preparation and Evaluation of Coloring Composition>

### Example 1

The coloring composition (S-1) was obtained by mixing 21.8 parts by mass of the pigment dispersion (R-1), 0.55 part by mass of the binder resin (C-2) solution (solids concentration: 40 mass %), 0.65 part by mass of the KAYARAD DPEA-12 (ethylene oxide-modified dipentaerythritol hexaacrylate, manufactured by Nippon Kayaku Co., Ltd.) as a polymerizable compound, 0.18 part by mass of 1,2-octanedione, 1-[4-(phenylthio)phenyl]-, 2-(O-benzoyloxime) (IRGACURE OXE 01 manufactured by BASF) as a photopolymerization initiator, 0.1 part by mass of the MEGAFACE F-554 (manufactured by DIC Corporation) as a fluorine-based surfactant, and 7.3 parts by mass of γ-butyrolactone.

### Evaluation on Storage Stability

The viscosity of the coloring composition (S-1) immediately after being prepared was measured by using an E type viscometer (manufactured by TOKYO KEIKI INC.). Next, the coloring composition (S-1) was filled in a light-shielding glass container and left to stand for 14 days at 23° C. in a sealed state, and the viscosity thereof was measured again by using an E type viscometer (manufactured by TOKYO KEIKI INC.). Thereafter, the rate of increase in viscosity after 14 days of storage with respect to the viscosity immediately after preparation was calculated. The evaluation criteria are as follows, and the results thereof are presented in Table 3.

Evaluation criteria

A: Rate of increase is less than 5%

B: Rate of increase is 5% or more and less than 10%

C: Rate of increase is 10% or more

### Evaluation on Film Thickness Uniformity

The composition for forming an undercoat film was applied on a 6 inch silicon wafer by a spin coating method using an automatic coating and developing apparatus (CLEAN TRACK manufactured by Tokyo Electron Limited, trade name “MARK-Vz”), and baked for 2 minutes at 250° C., thereby forming a undercoat film having a thickness of 0.6 μm.

The coloring composition (S-1) was applied on this undercoat film by a spin coating method and then prebaked for 120 seconds at 100° C., thereby forming a coating film having a thickness of 0.50 μm.

Film thickness was measured at the wafer center and the places at 1 cm intervals from the center of the wafer to the left and right (15 places including the wafer center) by a reflective spectroscopic film thickness meter (FE-3000 manufactured by OTSUKA ELECTRONICS Co., LTD.). The difference (Δft) between the maximum film thickness and the minimum film thickness in the wafer was calculated and evaluated according to the following criteria. The results thereof are presented in Table 3.

Evaluation criteria

A: Δft is less than 10 nm.

B: Δft is 10 nm or more and less than 30 nm.

C: Δft is 30 nm or more.

### <Formation and Evaluation of Colored Cured Film>

### Formation of Colored Cured Film

The composition for forming an undercoat film was applied on a 6 inch silicon wafer by a spin coating method using an automatic coating and developing apparatus (CLEAN TRACK manufactured by Tokyo Electron Limited, trade name “MARK-Vz”), and baked for 2 minutes at 250° C., thereby forming a undercoat film having a thickness of 0.6 μm.

The coloring composition (S-1) was applied on this undercoat film by a spin coating method and then prebaked for 120 seconds at 100° C., thereby forming a coating film having a thickness of 0.50 μm. Thereafter, the substrate thus obtained was cooled to room temperature, and the coating film on the substrate was subjected to pattern exposure by reduction projection exposure using an i-line stepper (NSR-2205i 12D manufactured by Nikon Corporation) via a photomask. The pattern exposure conducted at 105 places in total of the pattern arranged in a matrix shape of 15 rows×7 columns. At this time, the above 15 rows of the matrix were under a condition in which the exposure value was changed every one row at an interval of 50 mJ/cm² so that the minimum exposure value was 50 mJ/cm² and the maximum exposure value was 750 mJ/cm². In addition, the above 7 columns were under a condition in which the focal distance was changed at an interval of 0.2 μm by taking the optimum value (Focus 0.0 μm) of focal distance as the center. In other words, the above 7 columns were under a condition in which the focal distance was changed every one column by taking one column at the center as the optimum value of focal distance. In addition, as the photomask, a photomask in which a cured film was formed such that a square pixel pattern of 1.1 μm² was arranged within a range of 4 mm x 3 mm was used.

By conducting the same operation, two wafers having a cured film were fabricated.

The first wafer thus fabricated was subjected to puddle development using a 0.3 mass % aqueous solution of tetramethylammonium hydroxide for 30 seconds in an automatic coating and developing apparatus, rinsed with ultrapure water, spin-dried, and then post-baked for 300 seconds at 200° C. on a hot plate, thereby fabricating a substrate (1) having a colored cured film pattern.

In addition, the second wafer thus fabricated was subjected to puddle development using a 0.3 mass % aqueous solution of tetramethylammonium hydroxide for 30 seconds in an automatic coating and developing apparatus, rinsed with ultrapure water, and spin-dried. This wafer was again subjected to puddle development using a 0.3 mass % aqueous solution of tetramethylammonium hydroxide for 30 seconds in an automatic coating and developing apparatus, rinsed with ultrapure water, and spin-dried. This wafer was post-baked for 300 seconds at 200° C. on a hot plate, thereby fabricating a substrate (2) having a colored cured film pattern.

### Evaluation on Sensitivity and Pattern Shape

The size and cross-sectional shape of the colored cured film on the substrate (1) were observed by using the SU8030 (scanning electron microscope, manufactured by Hitachi, Ltd.). The evaluation criteria are as follows and the results thereof are presented in Table 3. In the cases of C and D, it can be said that the sensitivity of the radiation-sensitive coloring composition is low.

### Evaluation Criteria

A: The exposure value capable of forming a square pixel pattern of 1.1 μm² was in a range of from 50 to 750 mJ/cm², but the pattern cross-sectional shape formed at that time was a rectangle.

B: The exposure value capable of forming a square pixel pattern of 1.1 μm² was in a range of from 50 to 750 mJ/cm², and the pattern cross-sectional shape formed at that time was not a rectangle.

C: The exposure value capable of forming a square pixel pattern of 1.1 μm² was not in a range of from 50 to 750 mJ/cm², and the cross-sectional shape of any of the patterns formed at that time was not a rectangle.

D: The unexposed portion was hardly dissolved, and a pattern was not formed.

### Evaluation on Development Residues

The unexposed portion of the substrate (1) and the unexposed portion of the substrate (2) were observed by using the S-9220 (scanning electron microscope, manufactured by Hitachi, Ltd.), and development residues were evaluated. The evaluation criteria are as follows and the results thereof are presented in Table 3.

### Evaluation Criteria

A: Residues were not observed on the unexposed portion of the substrate (1) and the unexposed portion of the substrate (2) at all.

B: Residues were slightly observed on the unexposed portion of the substrate (1) but there was no problem in practical use. In addition, residues were not observed on the unexposed portion of the substrate (2) at all.

C: Residues were greatly observed on the unexposed portion of the substrate (1). In addition, residues were slightly observed on the unexposed portion of the substrate (2) but there was no problem in practical use.

D: Residues were significantly greatly observed on the unexposed portion of the substrate (1). In addition, residues were greatly observed on the unexposed portion of the substrate (2).

E: Residues were significantly greatly observed on both the unexposed portion of the substrate (1) and the unexposed portion of the substrate (2).

### Evaluation on Surface Roughness

The composition for forming an undercoat film was applied on a 6 inch silicon wafer by a spin coating method using an automatic coating and developing apparatus (CLEAN TRACK manufactured by Tokyo Electron Limited, trade name “MARK-Vz”), and baked for 2 minutes at 250° C., thereby forming a undercoat film having a thickness of 0.6 μm.

The coloring composition (S-1) was applied on this undercoat film by a spin coating method and then prebaked for 120 seconds at 100° C., thereby forming a coating film having a thickness of 0.50 μm. Thereafter, the substrate thus obtained was cooled to room temperature, and the coating film on the substrate was exposed by reduction projection exposure using an i-line stepper (NSR-2005i 10D manufactured by Nikon Corporation, exposure value of 500 mJ/cm² at a wavelength of 365 nm) via a photomask.

This substrate was subjected to puddle development using a 0.3 mass % aqueous solution of tetramethylammonium hydroxide for 30 seconds in an automatic coating and developing apparatus, rinsed with ultrapure water, spin-dried, and then post-baked for 300 seconds at 200° C. on a hot plate, thereby fabricating a silicon wafer having a square colored cured film with a side of 1 cm.

The surface roughness of the upper portion of the colored cured film formed on this silicon wafer was measured by using an atomic force microscope manufactured by Digital Instruments. The evaluation criteria are as follows and the results thereof are presented in Table 3.

### Evaluation Criteria

A: Surface roughness is 40 ø or less

B: Surface roughness is more than 40 ø and 60 ø or less

C: Surface roughness is more than 60 ø and 80 ø or less

D: Surface roughness is more than 80 ø, or it is unevaluable since pixel pattern cannot be formed

### Evaluation on Transmittance

The coloring composition (S-1) was applied on a glass substrate by a spin coating method and then heated for 180 seconds at 100° C. to form a coating film. Subsequently, the coating film on the substrate was entirely exposed (exposure value of 1,000 mJ/cm² at a wavelength of 365 nm). Subsequently, the coating film was brought into contact with an aqueous solution containing tetramethylammonium hydroxide at 0.3 mass % for 15 seconds, and then the coating film was washed with water. Thereafter, the glass substrate was heated for 300 seconds on a hot plate at 200° C., thereby obtaining a glass wafer having a colored cured film with a thickness of 0.50 μm.

The transmittance (% T) of the glass wafer having a colored cured film was measured by using a spectrophotometer (V-7300 manufactured by JASCO Corporation), and the transmittance at 400, 405, 410, 415, 420, 425, 430, 580, and 620 nm was determined. In addition, the maximum transmittance in a wavelength region of from 430 to 560 nm was determined. The results thereof are presented in Table 3. However, the transmittance in Table 3 is a value to that of a glass substrate, and the film thickness is a value measured by a stylus type profilometer (Alpha Step IQ manufactured by YAMATO SCIENTIFIC CO., LTD.). The evaluation criteria for the transmittance at the respective wavelengths are as follows, and it can be said that a colored cured film which satisfies all of the following evaluation criteria is a colored cured film which exhibits excellent color reproducibility, has a high transmittance, and hardly affects the transmissive regions of other colors.

### Evaluation Criteria

It is possible to efficiently shield light in violet to blue when the transmittance at 400 nm is 30% or less, the transmittance at 410 nm is 25% or less (more preferably 20% or less, and even more preferably 15% or less), the transmittance at 420 nm is 20% or less (more preferably 15% or less, and even more preferably 10% or less), and the transmittance at 430 nm is 15% or less (more preferably 13% or less, and even more preferably 10% or less).

It is possible to efficiently shield light in blue to green when the maximum transmittance in a wavelength region of from 430 to 560 nm is 15% or less.

It is possible to fabricate a solid-state imaging element which exhibits favorable color reproducibility when the transmittance at 580 nm is 50% or less since rising to switch from the absorption region to the transmissive region is moderate.

It is possible to fabricate a solid-state imaging element which exhibits favorable red color reproducibility when the transmittance at 620 nm is 80% or more since a red color sensing signal is sufficiently incorporated.

### Examples 2 to 9 and Comparative Examples 1 to 6

The coloring compositions (S-2) to (S-15) were prepared by changing the member and amount of the respective components as presented in Table 2 in Example 1. Subsequently, the evaluation was carried out in the same manner as in Example 1. The results thereof are presented in Table 3.

TABLE 2

| | | | Example 1 | Example 2 | Example 3 | Example 4 | Exampb 5 | Example 6 | Example 7 | Example 8 |
|---|---|---|---|---|---|---|---|---|---|---|
| Coloring composition | | | S-1 | S-2 | S-3 | S-4 | S-5 | S-6 | S-7 | S-8 |
| Pigment dispersion | | Kind | R-1 | R-2 | R-3 | R-4 | R-5 | R-6 | R-7 | R-8 |
| | | Kind and | R264/Y185 = | R264/Y185 = | R264/Y185 = | R264/Y185 = | R264/Y185 = | R264/Y185 = | R264/Y185 = | R264/Y139 = |
| | | proportion | 90/10 | 85/15 | 80/20 | 75/25 | 70/30 | 65/35 | 60/40 | 80/20 |
| | | of colorant | | | | | | | | |
| | | contained | | | | | | | | |
| | | Amount | 21.8 | 21.8 | 21.8 | 21.8 | 21.8 | 21.8 | 21.8 | 21.8 |
| (C) Binder | (C1) | C-5 | | | | | | | | |
| resin | | C-6 | | | | | | | | |
| | | C-7 | | | | | | | | |
| | | C-8 | | | | | | | | |
| | (C2) | C-1 | | | | | | | | |
| | | C-2 | 0.55 | 0.55 | 0.55 | 0.55 | 0.55 | 0.55 | 0.55 | 0.55 |
| | | C-3 | | | | | | | | |
| | | C-4 | | | | | | | | |
| (D) Polymer- | (D1) | D1-1 | 0.65 | 0.65 | 0.65 | 0.65 | 0.65 | 0.65 | 0.65 | 0.65 |
| izable | | D1-2 | | | | | | | | |
| compound | (D2) | D2-1 | | | | | | | | |
| (E) | (E1) | E1-1 | | | | | | | | |
| Photopoly- | | E1-2 | | | | | | | | |
| merization | | E1-3 | 0.18 | 0.18 | 0.18 | 0.18 | 0.18 | 0.18 | 0.18 | 0.18 |
| initiator | (E2) | E2-1 | | | | | | | | |
| | | E2-2 | | | | | | | | |
| Additive | (G) | G-1 | 0.1 | 0.1 | 0.1 | 0.1 | 0.1 | 0.1 | 0.1 | 0.1 |
| (F) Solvent | (F1) | PGME | | | | | | | | |
| | | PGEE | | | | | | | | |
| | | PNP | | | | | | | | |
| | | DAA | | | | | | | | |
| | | EL | | | | | | | | |
| | | CHN | | | | | | | | |
| | (F2) | γBL | 7.3 | 7.3 | 7.3 | 7.3 | 7.3 | 7.3 | 7.3 | 7.3 |
| | | EDGAC | | | | | | | | |
| | | DPMA | | | | | | | | |
| | (F3) | PGMEA | | | | | | | | |
| | | EEP | | | | | | | | |
| | | MBA | | | | | | | | |

| | | | | | | | | |
|---|---|---|---|---|---|---|---|---|
| Proportion of (F1) (%) | 13 | 13 | 13 | 13 | 13 | 13 | 13 | 13 |
| Proportion of (F2) (%) | 28 | 28 | 28 | 28 | 28 | 28 | 28 | 28 |
| Proportion of (F3) (%) | 59 | 59 | 59 | 59 | 59 | 59 | 59 | 59 |
| Concentration of pigment (%) | 50 | 50 | 50 | 50 | 50 | 50 | 50 | 50 |

| | | | | Comparative | Comparative | Comparative | Comparative | Comparative | Comparative |
|---|---|---|---|---|---|---|---|---|---|
| | | | Example 9 | Example 1 | Example 2 | Example 3 | Example 4 | Example 5 | Example 6 |
| Coloring composition | | | S-9 | S-10 | S-11 | S-12 | S-13 | S-14 | S-15 |
| Pigment dispersion | | Kind | R-9 | R-10 | R-11 | R-12 | R-13 | R-14 | R-15 |
| | | Kind and | R264/Y139 = | R254/Y185 = | R254 = 100 | R242/Y185 = | R177/Y185 = | R264/Y138 = | R264/7Y50 = |
| | | proportion | 70/30 | 80/20 | | 80/20 | 80/20 | 80/20 | 80/20 |
| | | of colorant | | | | | | | |
| | | contained | | | | | | | |
| | | Amount | 21.8 | 21.8 | 21.8 | 21.8 | 21.8 | 21.8 | 21.8 |
| (C) Binder | (C1) | C-5 | | | | | | | |
| resin | | C-6 | | | | | | | |
| | | C-7 | | | | | | | |
| | | C-8 | | | | | | | |
| | (C2) | C-1 | | | | | | | |
| | | C-2 | 0.55 | 0.55 | 0.55 | 0.55 | 0.55 | 0.55 | 0.55 |
| | | C-3 | | | | | | | |
| | | C-4 | | | | | | | |
| (D) Polymer- | (D1) | D1-1 | 0.65 | 0.65 | 0.65 | 0.65 | 0.65 | 0.65 | 0.65 |
| izable | | D1-2 | | | | | | | |
| compound | (D2) | D2-1 | | | | | | | |
| (E) | (E1) | E1-1 | | | | | | | |
| Photopoly- | | E1-2 | | | | | | | |
| merization | | E1-3 | 0.18 | 0.18 | 0.18 | 0.18 | 0.18 | 0.18 | 0.18 |
| initiator | (E2) | E2-1 | | | | | | | |
| | | E2-2 | | | | | | | |
| Additive | (G) | G-1 | 0.1 | 0.1 | 0.1 | 0.1 | 0.1 | 0.1 | 0.1 |
| (F) Solvent | (F1) | PGME | | | | | | | |
| | | PGEE | | | | | | | |
| | | PNP | | | | | | | |
| | | DAA | | | | | | | |
| | | EL | | | | | | | |
| | | CHN | | | | | | | |
| | (F2) | γBL | 7.3 | 7.3 | 7.3 | 7.3 | 7.3 | 7.3 | 7.3 |
| | | EDGAC | | | | | | | |
| | | DPMA | | | | | | | |
| | (F3) | PGMEA | | | | | | | |
| | | EEP | | | | | | | |
| | | MBA | | | | | | | |

| | | | | | | | |
|---|---|---|---|---|---|---|---|
| Proportion of (F1) (%) | 13 | 13 | 13 | 13 | 13 | 13 | 13 |
| Proportion of (F2) (%) | 28 | 28 | 28 | 28 | 28 | 28 | 28 |
| Proportion of (F3) (%) | 59 | 59 | 59 | 59 | 59 | 59 | 59 |
| Concentration of pigment (%) | 55 | 50 | 50 | 50 | 50 | 55 | 50 |

TABLE 3

| | | Example | | | | | | Example | Example |
|---|---|---|---|---|---|---|---|---|---|
| | | 1 | Example 2 | Example 3 | Example 4 | Example 5 | Example 6 | 7 | 8 |
| Sensitivity and pattern shape | | A | A | A | A | A | A | A | A |
| Development residues | | A | A | A | A | A | A | A | A |
| Surface roughness | | A | A | A | A | A | A | A | A |
| Film thickness uniformity | | A | A | A | A | A | A | A | A |
| Storage stability of coloring composition | | A | A | A | A | A | A | A | A |
| Evaluation on | Film thickness (μm) | 0.50 | 0.50 | 0.50 | 0.50 | 0.50 | 0.50 | 0.50 | 0.50 |
| transmittance | Transmittance at 400 nm (%) | 29 | 23 | 19 | 15 | 12 | 10 | 8 | 27 |
| | Transmittance at 405 nm (%) | 26 | 21 | 16 | 13 | 10 | 8 | 6 | 24 |
| | Transmittance at 410 nm (%) | 23 | 18 | 14 | 11 | 9 | 7 | 5 | 22 |
| | Transmittance at 415 nm (%) | 21 | 16 | 13 | 10 | 8 | 6 | 5 | 19 |
| | Transmittance at 420 nm (%) | 17 | 13 | 10 | 8 | 6 | 5 | 4 | 17 |
| | Transmittance at 425 nm (%) | 16 | 12 | 9 | 7 | 6 | 4 | 3 | 14 |
| | Transmittance at 430 nm (%) | 13 | 10 | 8 | 6 | 5 | 4 | 3 | 13 |
| | Maximum transmittance at | 13 | 10 | 10 | 11 | 13 | 15 | 17 | 13 |
| | 430 to 560 nm (%) | | | | | | | | |
| | Transmittance at 580 nm (%) | 16 | 17 | 19 | 21 | 23 | 26 | 28 | 19 |
| | Transmittance at 620 nm (%) | 86 | 86 | 87 | 88 | 88 | 89 | 90 | 86 |

| | | Example | Comparative | Comparative | Comparative | Comparative | Comparative | Comparative |
|---|---|---|---|---|---|---|---|---|
| | | 9 | Example 1 | Example 2 | Example 3 | Example 4 | Example 5 | Example 6 |
| Sensitivity and pattern shape | | A | A | A | A | A | A | A |
| Development residues | | A | A | A | A | A | A | A |
| Surface roughness | | A | A | A | A | A | A | A |
| Film thickness uniformity | | A | A | A | A | A | A | A |
| Storage stability of coloring composition | | A | A | A | A | A | A | A |
| Evaluation on | Film thickness (μm) | 0.50 | 0.50 | 0.50 | 0.50 | 0.50 | 0.50 | 0.50 |
| transmittance | Transmittance at 400 nm (%) | 20 | 22 | 56 | 11 | 19 | 36 | 34 |
| | Transmittance at 405 nm (%) | 18 | 19 | 51 | 9 | 17 | 32 | 30 |
| | Transmittance at 410 nm (%) | 16 | 16 | 46 | 8 | 16 | 28 | 26 |
| | Transmittance at 415 nm (%) | 14 | 15 | 41 | 7 | 15 | 24 | 22 |
| | Transmittance at 420 nm (%) | 12 | 12 | 35 | 6 | 13 | 21 | 19 |
| | Transmittance at 425 nm (%) | 10 | 11 | 31 | 6 | 13 | 17 | 16 |
| | Transmittance at 430 nm (%) | 9 | 9 | 26 | 6 | 12 | 14 | 13 |
| | Maximum transmittance at | 12 | 12 | 26 | 34 | 29 | 14 | 13 |
| | 430 to 560 nm (%) | | | | | | | |
| | Transmittance at 580 nm (%) | 24 | 58 | 52 | 83 | 34 | 19 | 19 |
| | Transmittance at 620 nm (%) | 87 | 95 | 94 | 96 | 94 | 86 | 87 |

In Table 2, the respective components are as follows.

D1-1: KAYARAD DPEA-12 (ethylene oxide-modified dipentaerythritol hexaacrylate, manufactured by Nippon Kayaku Co., Ltd.)

D1-2: monoesterified product of dipentaerythritol pentaacrylate and succinic acid, mixture of dipentaerythritol hexaacrylate and dipentaerythritol pentaacrylate (trade name: TO-1382 manufactured by TOAGOSEI CO., LTD.)

D2-1: pentaerythritol tetraacrylate (ARONIX M-450 manufactured by TOAGOSEI CO., LTD.)

E1-1: ADEKA ARKLS NCI-930 (manufactured by ADEKA CORPORATION) E1-2: ethanone-1-[9-ethyl-6-(2-methylbenzoyl)-9H-carbazol-3-yl]-1-(O-acetyloxime)] (trade name: IRGACURE OXE 02 manufactured by BASF)

E1-3: 1,2-octanedione, 1-[4-(phenylthio)phenyl]-, 2-(O-benzoyloxime) (IRGACURE OXE 01 manufactured by BASF)

E2-1: 2,4-diethylthioxanthone

E2-2: 2-benzyl-2-dimethylamino-1-(4-morpholinophenyl)butan-1-one (trade name: IRGACURE 369 manufactured by BASF)

G-1: MEGAFACE F-554 (manufactured by DIC Corporation)

### Examples 10 to 14

The coloring compositions (S-16) to (S-20) were prepared in the same manner as in Example 3 except that the amount of the respective components was changed as presented in Table 4 in Example 3. Subsequently, the evaluation was carried out in the same manner as in Example 3. The results thereof are presented in Table 5.

TABLE 4

| | | | Example | Example | Example | Example | Example |
|---|---|---|---|---|---|---|---|
| | | | 10 | 11 | 12 | 13 | 14 |
| Coloring composition | | | S-16 | S-17 | S-18 | S-19 | S-20 |
| Pigment dispersion | | Kind | R-3 | R-3 | R-3 | R-3 | R-3 |
| | | Kind and proportion | R264/Y185 = | R264/Y185 = | R264/Y185 = | R264/Y185 = | R264/Y185 = |
| | | of colorant contained | 80/20 | 80/20 | 80/20 | 80/20 | 80/20 |
| | | Amount | 15.26 | 17.44 | 19.62 | 23.98 | 26.16 |
| (C) Binder resin | (C1) | C-5 | | | | | |
| | | C-6 | | | | | |
| | | C-7 | | | | | |
| | | C-8 | | | | | |
| | (C2) | C-1 | | | | | |
| | | C-2 | 2 | 1.5 | 1 | 0.6 | 0.5 |
| | | C-3 | | | | | |
| | | C-4 | | | | | |
| (D) Polymerizable | (D1) | D1-1 | 1.08 | 0.94 | 0.8 | 0.32 | 0.09 |
| compound | | D1-2 | | | | | |
| | (D2) | D2-1 | | | | | |
| (E) | (E1) | E1-1 | | | | | |
| Photopolymerization | | E1-2 | | | | | |
| initiator | | E1-3 | 0.28 | 0.24 | 0.21 | 0.13 | 0.03 |
| | (E2) | E2-1 | | | | | |
| | | E2-2 | | | | | |
| Additive | (G) | G-1 | 0.1 | 0.1 | 0.1 | 0.1 | 0.1 |
| (F) Solvent | (F1) | PGME | 1.17 | 0.78 | 0.39 | | |
| | | PGEE | | | | | |
| | | PNP | | | | | |
| | | DAA | | | | | |
| | | EL | | | | | |
| | | CHN | | | | | |
| | (F2) | γBL | 7.3 | 7.3 | 7.3 | 7.3 | 7.3 |
| | | EDGAC | | | | | |
| | | DPMA | | | | | |
| | (F3) | PGMEA | 3.39 | 2.28 | 1.16 | | |
| | | EEP | | | | | |
| | | MBA | | | | | |

| | | | | | |
|---|---|---|---|---|---|
| Proportion of (F1) (%) | 14 | 13 | 13 | 13 | 13 |
| Proportion of (F2) (%) | 29 | 29 | 29 | 27 | 25 |
| Proportion of (F3) (%) | 58 | 58 | 58 | 60 | 62 |
| Concentration of pigment (%) | 35 | 40 | 45 | 55 | 60 |

TABLE 5

| | | Example | Example | Example | Example | Example |
|---|---|---|---|---|---|---|
| | | 10 | 11 | 12 | 13 | 14 |
| Evaluation on sensitivity and pattern shape | | A | A | A | B | C |
| Development residues | | A | A | A | B | C |
| Surface roughness | | A | A | A | B | B |
| Film thickness uniformity | | A | A | A | B | C |
| Security of coloring composition | | A | A | A | A | A |
| Evaluation on | Film thickness (μm) | 0.50 | 0.50 | 0.50 | 0.50 | 0.50 |
| transmittance | Transmittance at 400 nm(%) | 31 | 26 | 22 | 16 | 13 |
| | Transmittance at 405 nm(%) | 28 | 23 | 19 | 13 | 11 |
| | Transmittance at 410 nm(%) | 26 | 21 | 17 | 12 | 10 |
| | Transmittance at 415 nm(%) | 24 | 19 | 16 | 11 | 9 |
| | Transmittance at 420 nm(%) | 20 | 16 | 13 | 8 | 6 |
| | Transmittance at 425 nm(%) | 19 | 15 | 12 | 7 | 6 |
| | Transmittance at 430 nm(%) | 17 | 13 | 10 | 6 | 5 |
| | Maximum transmittance at | 19 | 15 | 12 | 8 | 6 |
| | 430 to 560 nm(%) | | | | | |
| | Transmittance at 580 nm(%) | 31 | 27 | 23 | 16 | 14 |
| | Transmittance at 620 nm(%) | 91 | 89 | 88 | 86 | 84 |

### Examples 15 to 20

The evaluation on transmittance was carried out in the same manner as in Example 3 except that the thickness of the coating film formed on the undercoat film was changed as presented in Table 6 in Example 3. The results thereof are presented in Table 6. The evaluation results on sensitivity and pattern shape, development residues, surface roughness, film thickness uniformity, and storage stability of the coloring composition in Examples 15 to 20 are the same as those in Example 3, and the description thereon is thus omitted.

TABLE 6

| | | Example | Example | Example | Example | Example | Example |
|---|---|---|---|---|---|---|---|
| | | 15 | 16 | 17 | 18 | 19 | 20 |
| Evaluation on | Film thickness (μm) | 0.60 | 0.55 | 0.50 | 0.45 | 0.40 | 0.35 |
| transmittance | Transmittance at 400 nm (%) | 13 | 16 | 19 | 22 | 26 | 31 |
| | Transmittance at 405 nm (%) | 11 | 13 | 16 | 19 | 23 | 28 |
| | Transmittance at 410 nm (%) | 10 | 12 | 14 | 17 | 21 | 26 |
| | Transmittance at 415 nm (%) | 9 | 11 | 13 | 16 | 19 | 24 |
| | Transmittance at 420 nm (%) | 6 | 8 | 10 | 13 | 16 | 20 |
| | Transmittance at 425 nm (%) | 6 | 7 | 9 | 12 | 15 | 19 |
| | Transmittance at 430 nm (%) | 5 | 6 | 8 | 10 | 13 | 17 |
| | Maximum transmittance at | 6 | 8 | 10 | 12 | 15 | 19 |
| | 430 to 560 nm (%) | | | | | | |
| | Transmittance at 580 nm (%) | 14 | 16 | 19 | 23 | 27 | 31 |
| | Transmittance at 620 nm (%) | 84 | 86 | 87 | 88 | 89 | 91 |

### Preparation Examples 16 to 20

The pigment dispersions (R-16) to (R-20) were prepared in the same manner as in Preparation Example 3 except that the member of the colorant used was changed as presented in Table 7 in Preparation Example 3.

### Examples 21 to 25

Coloring compositions (S-21) to (S-25) were prepared in the same manner as in Example 3 except that the member of the pigment dispersion used was changed as presented in Table 8 in Example 3. Subsequently, the evaluation was carried out in the same manner as in Example 3. The results thereof are presented in Table 8. The results of the evaluation on transmittance in Examples 21 to 25 are the same as those in Example 3, and the description thereon is thus omitted.

TABLE 7

| | | | Preparation | Preparation | Preparation | Preparation | Preparation |
|---|---|---|---|---|---|---|---|
| | | | Example 16 | Example 17 | Example 18 | Example 19 | Example 20 |
| Pigment dispersion | | | R-16 | R-17 | R-18 | R-19 | R-20 |
| (A) Colorant | | R264 (11 nm) | 8.8 | | | | |
| | | R264 (22 nm) | | 8.8 | | | |
| | | R264 (39 nm) | | | | | |
| | | R264 (58 nm) | | | 8.8 | | |
| | | R264 (83 nm) | | | | 8.8 | |
| | | R264 (104 nm) | | | | | 8.8 |
| | | R254 (41 nm) | | | | | |
| | | R242 (42 nm) | | | | | |
| | | R177 (38 nm) | | | | | |
| | | Y185 (12 nm) | 2.2 | | | | |
| | | Y185 (20 nm) | | 2.2 | | | |
| | | Y185 (42 nm) | | | | | |
| | | Y185 (60 nm) | | | 2.2 | | |
| | | Y185 (81 nm) | | | | 2.2 | |
| | | Y185 (103 nm) | | | | | 2.2 |
| | | Y139 (40 nm) | | | | | |
| | | Y150 (41 nm) | | | | | |
| | | Y138 (41 nm) | | | | | |
| Dispersion auxiliary | | α | 0.4 | 0.4 | 0.4 | 0.4 | 0.4 |
| | | β | | | | | |
| | | γ | | | | | |
| (B) Dispersant | (B1) | Dispersant (B-1) | 8.45 | 8.45 | 8.45 | 8.45 | 8.45 |
| | | LPN6919 | | | | | |
| | | LPN21116 | | | | | |
| | (B2) | byk2001 | | | | | |
| (C) Binder resin | (C1) | C-5 | | | | | |
| | | C-6 | | | | | |
| | | C-7 | | | | | |
| | | C-8 | 4.9 | 4.9 | 4.9 | 4.9 | 4.9 |
| | (C2) | C-1 | | | | | |
| | | C-2 | | | | | |
| | | C-3 | | | | | |
| | | C-4 | | | | | |
| (F) Solvent | (F1) | PGME | 15 | 15 | 15 | 15 | 15 |
| | | PGEE | | | | | |
| | | PNP | | | | | |
| | | DAA | | | | | |
| | | EL | | | | | |
| | | CHN | | | | | |
| | (F2) | γBL | | | | | |
| | | EDGAC | | | | | |
| | | DPMA | | | | | |
| | (F3) | PGMEA | 60.25 | 60.25 | 60.25 | 60.25 | 60.25 |
| | | EEP | | | | | |
| | | MBA | | | | | |

TABLE 8

| | | Example | Example | Example | Example | Example |
|---|---|---|---|---|---|---|
| | | 21 | 22 | 23 | 24 | 25 |
| Coloring composition | | S-21 | S-22 | S-23 | S-24 | S-25 |
| Pigment dispersion | Kind | R-16 | R-17 | R-18 | R-19 | R-20 |
| | Kind and | R264/Y185 = | R264/Y185 = | R264/Y185 = | R264/Y185 = | R264/Y185 = |
| | proportion of | 80/20 | 80/20 | 80/20 | 80/20 | 80/20 |
| | colorant | | | | | |
| | contained | | | | | |
| | Amount | 21.8 | 21.8 | 21.8 | 21.8 | 21.8 |

| | | | | | |
|---|---|---|---|---|---|
| Sensitivity and pattern shape | A | A | A | A | A |
| Development residues | A | A | A | A | A |
| Surface roughness | A | A | B | B | C |
| Film thickness uniformity | A | A | A | A | A |
| Storage stability of coloring composition | B | A | A | A | A |

### Preparation Examples 21 to 29

The pigment dispersions (R-21) to (R-29) were prepared in the same manner as in Preparation Example 3 except that the member of the solvent used was changed as presented in Table 9 in Preparation Example 3.

### Examples 26 to 34

The coloring compositions (S-26) to (S-34) were prepared in the same manner as in Example 3 except that the member of the pigment dispersion used was changed as presented in Table 10 in Example 3. Subsequently, the evaluation was carried out in the same manner as in Example 3. The results thereof are presented in Table 10. The results of the evaluation on transmittance in Examples 26 to 34 are the same as those in Example 3, and the description thereon is thus omitted.

TABLE 9

| | | | Preparation | Preparation | Preparation | Preparation | Preparation | Preparation | Preparation | Preparation | Preparation |
|---|---|---|---|---|---|---|---|---|---|---|---|
| | | | Example | Example | Example | Example | Example | Example | Example | Example | Example |
| | | | 21 | 22 | 23 | 24 | 25 | 26 | 27 | 28 | 29 |
| Pigment dispersion | | | R-21 | R-22 | R-23 | R-24 | R-25 | R-26 | R-27 | R-28 | R-29 |
| (A) Colorant | | R264 (11 nm) | | | | | | | | | |
| | | R264 (22 nm) | | | | | | | | | |
| | | R264 (39 nm) | 8.8 | 8.8 | 8.8 | 8.8 | 8.8 | 8.8 | 8.8 | 8.8 | 8.8 |
| | | R264 (58 nm) | | | | | | | | | |
| | | R264 (83 nm) | | | | | | | | | |
| | | R264 (104 nm) | | | | | | | | | |
| | | R254 (41 nm) | | | | | | | | | |
| | | R242 (42 nm) | | | | | | | | | |
| | | R177 (38 nm) | | | | | | | | | |
| | | Y185 (12 nm) | | | | | | | | | |
| | | Y185 (20 nm) | | | | | | | | | |
| | | Y185 (42 nm) | 2.2 | 2.2 | 2.2 | 2.2 | 2.2 | 2.2 | 2.2 | 2.2 | 2.2 |
| | | Y185 (60 nm) | | | | | | | | | |
| | | Y185 (81 nm) | | | | | | | | | |
| | | Y185 (103 nm) | | | | | | | | | |
| | | Y139 (40 nm) | | | | | | | | | |
| | | Y150 (41 nm) | | | | | | | | | |
| | | Y138 (41 nm) | | | | | | | | | |
| Dispersion | | α | 0.4 | 0.4 | 0.4 | 0.4 | 0.4 | 0.4 | 0.4 | 0.4 | 0.4 |
| auxiliary | | β | | | | | | | | | |
| | | γ | | | | | | | | | |
| (B) | (B1) | Dispersant | 8.45 | 8.45 | 8.45 | 8.45 | 8.45 | 8.45 | 8.45 | 8.45 | 8.45 |
| Dispersant | | (B-1) | | | | | | | | | |
| | | LPN6919 | | | | | | | | | |
| | | LPN21116 | | | | | | | | | |
| | (B2) | byk2001 | | | | | | | | | |
| (C) Binder | (C1) | C-5 | | | | | | | | | |
| resin | | C-6 | | | | | | | | | |
| | | C-7 | | | | | | | | | |
| | | C-8 | 4.9 | 4.9 | 4.9 | 4.9 | 4.9 | 4.9 | 4.9 | 4.9 | 4.9 |
| | (C2) | C-1 | | | | | | | | | |
| | | C-2 | | | | | | | | | |
| | | C-3 | | | | | | | | | |
| | | C-4 | | | | | | | | | |
| (F) | (F1) | PGME | 2.30 | 3.59 | 8.37 | 11.7 | 29.4 | 35.3 | 41.2 | 47.1 | 53 |
| Solvent | | PGEE | | | | | | | | | |
| | | PNP | | | | | | | | | |
| | | DAA | | | | | | | | | |
| | | EL | | | | | | | | | |
| | | CHN | | | | | | | | | |
| | (F2) | γBL | | | | | | | | | |
| | | EDGAC | | | | | | | | | |
| | | DPMA | | | | | | | | | |
| | (F3) | PGMEA | 72.86 | 71.66 | 66.88 | 63.55 | 45.85 | 39.95 | 34.05 | 28.15 | 22.25 |
| | | EEP | | | | | | | | | |
| | | MBA | | | | | | | | | |

TABLE 10

| | | | Example | Example | Example | Example | Example | Example | Example | Example | Example |
|---|---|---|---|---|---|---|---|---|---|---|---|
| | | | 26 | 27 | 28 | 29 | 30 | 31 | 32 | 33 | 34 |
| Coloring composition | | | S-26 | S-27 | S-28 | S-29 | S-30 | S-31 | S-32 | S-33 | S-34 |
| Pigment dispersion 1 | | Kind | R-21 | R-22 | R-23 | R-24 | R-25 | R-26 | R-27 | R-28 | R-29 |
| | | Kind and | R264/ | R264/ | P264/ | R264/ | R264/ | R264/ | R264/ | R264/ | R264/ |
| | | proportion | Y185 = | Y185 = | Y185 = | Y185 = | Y185 = | Y185 = | Y185 = | Y185 = | Y185 = |
| | | of colorant | 80/20 | 80/20 | 80/20 | 80/20 | 80/20 | 80/20 | 80/20 | 80/20 | 80/20 |
| | | contained | | | | | | | | | |
| | | Amount | 21.8 | 21.8 | 21.8 | 21.8 | 21.8 | 21.8 | 21.8 | 21.8 | 21.8 |
| Pigment dispersion 2 | | Kind | | | | | | | | | |
| | | Kind and | | | | | | | | | |
| | | proportion | | | | | | | | | |
| | | of colorant | | | | | | | | | |
| | | contained | | | | | | | | | |
| | | Amount | | | | | | | | | |
| (C) Binder resin | (C1) | C-5 | | | | | | | | | |
| | | C-6 | | | | | | | | | |
| | | C-7 | | | | | | | | | |
| | | C-8 | | | | | | | | | |
| | (C2) | C-1 | | | | | | | | | |
| | | C-2 | 0.55 | 0.55 | 0.55 | 0.55 | 0.55 | 0.55 | 0.55 | 0.55 | 0.55 |
| | | C-3 | | | | | | | | | |
| | | C-4 | | | | | | | | | |
| (D) Polymerizable | (D1) | D1-1 | 0.65 | 0.65 | 0.65 | 0.65 | 0.65 | 0.65 | 0.65 | 0.65 | 0.65 |
| compound | | D1-2 | | | | | | | | | |
| | (D2) | D2-1 | | | | | | | | | |
| (E) Photopolymerization | (E1) | E1-1 | | | | | | | | | |
| initiator | | E1-2 | | | | | | | | | |
| | | E1-3 | 0.18 | 0.18 | 0.18 | 0.18 | 0.18 | 0.18 | 0.18 | 0.18 | 0.18 |
| | (E2) | E2-1 | | | | | | | | | |
| | | E2-2 | | | | | | | | | |
| Additive | (G) | G-1 | 0.1 | 0.1 | 0.1 | 0.1 | 0.1 | 0.1 | 0.1 | 0.1 | 0.1 |
| (F) Solvent | (F1) | PGME | | | | | | | | | |
| | | PGEE | | | | | | | | | |
| | | PNP | | | | | | | | | |
| | | DAA | | | | | | | | | |
| | | EL | | | | | | | | | |
| | | CHN | | | | | | | | | |
| | (F2) | γBL | 7.3 | 7.3 | 7.3 | 7.3 | 7.3 | 7.3 | 7.3 | 7.3 | 7.3 |
| | | EDGAC | | | | | | | | | |
| | | DPMA | | | | | | | | | |
| | (F3) | PGMEA | | | | | | | | | |
| | | EEP | | | | | | | | | |
| | | MBA | | | | | | | | | |

| | | | | | | | | | |
|---|---|---|---|---|---|---|---|---|---|
| Proportion of (F1)(%) | 2 | 3 | 7 | 10 | 25 | 30 | 35 | 40 | 45 |
| Proportion of (F2)(%) | 28 | 28 | 28 | 28 | 28 | 28 | 28 | 28 | 28 |
| Proportion of (F3)(%) | 70 | 69 | 64 | 62 | 47 | 42 | 37 | 32 | 27 |
| Concentration of pigment (%) | 50 | 50 | 50 | 50 | 50 | 50 | 50 | 50 | 50 |
| Sensitivity and pattern shape | A | A | A | A | A | A | A | B | B |
| Development residues | A | A | A | A | A | A | A | A | A |
| Surface roughness | A | A | A | A | A | A | A | A | A |
| Film thickness uniformity | C | B | B | A | A | A | B | B | C |
| Storage stability of coloring composition | A | A | A | A | A | B | B | B | B |

### Examples 35 to 40

The coloring compositions (S-35) to (S-40) were prepared in the same manner as in Example 3 except that the member of the solvent used was changed as presented in Table 11 in Example 3. Subsequently, the evaluation was carried out in the same manner as in Example 3. The results thereof are presented in Table 11. The results of the evaluation on transmittance in Examples 35 to 40 are the same as those in Example 3, and the description thereon is thus omitted.

TABLE 11

| | | | Example | Example | Example | Example | Example | Example |
|---|---|---|---|---|---|---|---|---|
| | | | 35 | 36 | 37 | 38 | 39 | 40 |
| Coloring composition | | | S-35 | S-36 | S-37 | S-38 | S-39 | S-40 |
| Pigment dispersion 1 | | Kind | R-3 | R-3 | R-3 | R-3 | R-3 | R-3 |
| | | Kind and proportion | R264/Y185 = | R264/Y185 = | R264/Y185 = | R264/Y185 = | R264/Y185 = | R264/Y185 = |
| | | of colorant contained | 80/20 | 80/20 | 80/20 | 80/20 | 80/20 | 80/20 |
| | | Amount | 21.8 | 21.8 | 21.8 | 21.8 | 21.8 | 21.8 |
| Pigment dispersion 2 | | Kind | | | | | | |
| | | Kind and proportion | | | | | | |
| | | of colorant contained | | | | | | |
| | | Amount | | | | | | |
| (C) Binder resin | (C1) | C-5 | | | | | | |
| | | C-6 | | | | | | |
| | | C-7 | | | | | | |
| | | C-8 | | | | | | |
| | (C2) | C-1 | | | | | | |
| | | C-2 | 0.55 | 0.55 | 0.55 | 0.55 | 0.55 | 0.55 |
| | | C-3 | | | | | | |
| | | C-4 | | | | | | |
| (D) Polymerizable | (D1) | D1-1 | 0.65 | 0.65 | 0.65 | 0.65 | 0.65 | 0.65 |
| compound | | D1-2 | | | | | | |
| | (D2) | D2-1 | | | | | | |
| (E) Photopolymerization | (E1) | E1-1 | | | | | | |
| initiator | | E1-2 | | | | | | |
| | | E1-3 | 0.18 | 0.18 | 0.18 | 0.18 | 0.18 | 0.18 |
| | (E2) | E2-1 | | | | | | |
| | | E2-2 | | | | | | |
| Additive | (G) | G-1 | 0.1 | 0.1 | 0.1 | 0.1 | 0.1 | 0.1 |
| (F) Solvent | (F1) | PGME | | | | | | |
| | | PGEE | | | | | | |
| | | PNP | | | | | | |
| | | DAA | | | | | | |
| | | EL | | | | | | |
| | | CHN | | | | | | |
| | (F2) | γBL | | 0.78 | 1.83 | 2.6 | 12 | 15 |
| | | EDGAC | | | | | | |
| | | DPMA | | | | | | |
| | (F3) | PGMEA | 7.3 | 6.52 | 5.47 | 4.7 | | |
| | | EEP | | | | | | |
| | | MBA | | | | | | |

| | | | | | | |
|---|---|---|---|---|---|---|
| Proportion of (F1) (%) | 13 | 13 | 13 | 13 | 11 | 10 |
| Proportion of (F2) (%) | 0 | 3 | 7 | 10 | 40 | 45 |
| Proportion of (F3) (%) | 87 | 84 | 80 | 77 | 50 | 45 |
| Concentation of pigment (%) | 50 | 50 | 50 | 50 | 50 | 50 |
| Sensitivity and pattern shape | A | A | A | A | A | A |
| Development residues | D | C | B | A | A | A |
| Surface roughness | A | A | A | A | A | A |
| Film thickness uniformity | A | A | A | A | A | A |
| Storage stability of coloring composition | A | A | A | A | A | B |

### Preparation Examples 30 to 36

The pigment dispersions (R-30) to (R-36) were prepared in the same manner as in Preparation Example 3 except that the member of the solvent used was changed as presented in Table 12 in Preparation Example 3.

### Examples 41 to 49

The coloring compositions (S-41) to (S-49) were prepared in the same manner as in Example 3 except that the member of the pigment dispersion used was changed as presented in Table 13 in Example 3. Subsequently, the evaluation was carried out in the same manner as in Example 3. The results thereof are presented in Table 10. The results of the evaluation on transmittance in Examples 41 to 49 are the same as those in Example 3, and the description thereon is thus omitted.

TABLE 12

| | | | Preparation | Preparation | Preparation | Preparation | Preparation | Preparation | Preparation |
|---|---|---|---|---|---|---|---|---|---|
| | | | Example 30 | Example 31 | Example 32 | Example 33 | Example 34 | Example 35 | Example 36 |
| Pigment dispersion | | | R-30 | R-31 | R-32 | R-33 | R-34 | R-35 | R-36 |
| (A) Colorant | | R264 (11 nm) | | | | | | | |
| | | R264 (22 nm) | | | | | | | |
| | | R264 (39 nm) | 8.8 | 8.8 | 8.8 | 8.8 | 8.8 | 8.8 | 8.8 |
| | | R264 (58 nm) | | | | | | | |
| | | R264 (83 nm) | | | | | | | |
| | | R334 (104 nm) | | | | | | | |
| | | R254 (41 nm) | | | | | | | |
| | | R242 (42 nm) | | | | | | | |
| | | R177 (38 nm) | | | | | | | |
| | | Y185 (12 nm) | | | | | | | |
| | | Y185 (20 nm) | | | | | | | |
| | | Y185 (42 nm) | 2.2 | 2.2 | 2.2 | 2.2 | 2.2 | 2.2 | 2.2 |
| | | Y185 (60 nm) | | | | | | | |
| | | Y185 (81 nm) | | | | | | | |
| | | Y185 (103 nm) | | | | | | | |
| | | Y139 (40 nm) | | | | | | | |
| | | Y150 (41 nm) | | | | | | | |
| | | Y138 (41 nm) | | | | | | | |
| Dispersion auxiliary | | α | 0.4 | 0.4 | 0.4 | 0.4 | 0.4 | 0.4 | 0.4 |
| | | β | | | | | | | |
| | | γ | | | | | | | |
| (B) | (B1) | Dispersant (B-1) | 8.45 | 8.45 | 8.45 | 8.45 | 8.45 | 8.45 | 8.45 |
| Dispersant | | LPN6919 | | | | | | | |
| | | LPN21116 | | | | | | | |
| | (B2) | byk2001 | | | | | | | |
| (C) Binder | (C1) | C-5 | | | | | | | |
| resin | | C-6 | | | | | | | |
| | | C-7 | | | | | | | |
| | | C-8 | 4.9 | 4.9 | 4.9 | 4.9 | 4.9 | 4.9 | 4.9 |
| | (C2) | C-1 | | | | | | | |
| | | C-2 | | | | | | | |
| | | C-3 | | | | | | | |
| | | C-4 | | | | | | | |
| (F)Solvent | (F1) | PGME | | | | | | 15 | 15 |
| | | PGEE | 15 | | | | | | |
| | | PNP | | 15 | | | | | |
| | | DAA | | | 15 | | | | |
| | | EL | | | | 15 | | | |
| | | CHN | | | | | 15 | | |
| | (F2) | γBL | | | | | | | |
| | | EDGAC | | | | | | | |
| | | DPMA | | | | | | | |
| | (F3) | PGMEA | 60.25 | 60.25 | 60.25 | 60.25 | 60.25 | | |
| | | EEP | | | | | | 60.25 | |
| | | MBA | | | | | | | 60.25 |

TABLE 13

| | | | Example | Example | Example | Example | Example | Example | Example | Example | Example |
|---|---|---|---|---|---|---|---|---|---|---|---|
| | | | 41 | 42 | 43 | 44 | 45 | 46 | 47 | 48 | 49 |
| Coloring composition | | | S-41 | S-42 | S-43 | S-44 | S-45 | S-46 | S-47 | S-48 | S-49 |
| Pigment dispersion 1 | | Kind | R-30 | R-31 | R-32 | R-33 | R-34 | R-3 | R-3 | R-35 | R-36 |
| | | Kind and | R264/ | R264/ | R264/ | R264/ | R264/ | R264/ | R264/ | R264/ | R264/ |
| | | proportion | Y185 = | Y185 = | Y185 = | Y185 = | Y185 = | Y185 = | Y185 = | Y185 = | Y185 = |
| | | of colorant | 80/20 | 80/20 | 80/20 | 80/20 | 80/20 | 80/20 | 80/20 | 80/20 | 80/20 |
| | | contained | | | | | | | | | |
| | | Amount | 21.8 | 21.8 | 21.8 | 21.8 | 21.8 | 21.8 | 21.8 | 21.8 | 21.8 |
| Pigment dispersion 2 | | Kind | | | | | | | | | |
| | | Kind and | | | | | | | | | |
| | | proportion | | | | | | | | | |
| | | of colorant | | | | | | | | | |
| | | contained | | | | | | | | | |
| | | Amount | | | | | | | | | |
| (C) Binder resin | (C1) | C-5 | | | | | | | | | |
| | | C-6 | | | | | | | | | |
| | | C-7 | | | | | | | | | |
| | | C-8 | | | | | | | | | |
| | (C2) | C-1 | | | | | | | | | |
| | | C-2 | 0.55 | 0.55 | 0.55 | 0.55 | 0.55 | 0.55 | 0.55 | 0.55 | 0.55 |
| | | C-3 | | | | | | | | | |
| | | C-4 | | | | | | | | | |
| (D) Polymerizable | (D1) | D1-1 | 0.65 | 0.65 | 0.65 | 0.65 | 0.65 | 0.65 | 0.65 | 0.65 | 0.65 |
| compound | | D1-2 | | | | | | | | | |
| | (D2) | D2-1 | | | | | | | | | |
| (E) Photopolymerization | (E1) | E1-1 | | | | | | | | | |
| initiator | | E1-2 | | | | | | | | | |
| | | E1-3 | 0.18 | 0.18 | 0.18 | 0.18 | 0.18 | 0.18 | 0.18 | 0.18 | 0.18 |
| | (E2) | E2-1 | | | | | | | | | |
| | | E2-2 | | | | | | | | | |
| Additive | (G) | G-1 | 0.1 | 0.1 | 0.1 | 0.1 | 0.1 | 0.1 | 0.1 | 0.1 | 0.1 |
| (F) Solvent | (F1) | PGME | | | | | | | | | |
| | | PGEE | | | | | | | | | |
| | | PNP | | | | | | | | | |
| | | DAA | | | | | | | | | |
| | | EL | | | | | | | | | |
| | | CHN | | | | | | | | | |
| | (F2) | γBL | 7.3 | 7.3 | 7.3 | 7.3 | 7.3 | | | 7.3 | 7.3 |
| | | EDGAC | | | | | | 7.3 | | | |
| | | DPMA | | | | | | | 7.3 | | |
| | (F3) | PGMEA | | | | | | | | | |
| | | EEP | | | | | | | | | |
| | | MBA | | | | | | | | | |

| | | | | | | | | | |
|---|---|---|---|---|---|---|---|---|---|
| Proportion of (F1) (%) | 13 | 13 | 13 | 13 | 13 | 13 | 13 | 13 | 13 |
| Proportion of (F2) (%) | 28 | 28 | 28 | 28 | 28 | 28 | 28 | 28 | 28 |
| Proportion of (F3) (%) | 59 | 59 | 59 | 59 | 59 | 59 | 59 | 59 | 59 |
| Concentration of pigment (%) | 50 | 50 | 50 | 50 | 50 | 50 | 50 | 50 | 50 |
| Sensitivity and pattern shape | A | A | A | A | A | A | A | A | A |
| Development residues | A | A | A | A | A | A | A | A | A |
| Surface roughness | A | A | A | A | A | A | A | A | A |
| Film thickness uniformity | A | A | A | A | A | A | A | A | A |
| Storage stability of coloring composition | A | A | A | A | A | A | A | A | A |

### Examples 50 to 59

The coloring compositions (S-50) to (S-59) were prepared in the same manner as in Example 1 except that the member and amount of the pigment dispersion and component (D) or component (E) were changed as presented in Table 14 in Example 1. Subsequently, the evaluation was carried out in the same manner as in Example 1. The results thereof are presented in Table 14. The results of the evaluation on transmittance in Examples 50 to 59 are the same as those in Example 3, and the description thereon is thus omitted.

TABLE 14

| | | | Example | Example | Example | Example | Example | Example | Example | Example | Example | Example |
|---|---|---|---|---|---|---|---|---|---|---|---|---|
| | | | 50 | 51 | 52 | 53 | 54 | 55 | 56 | 57 | 58 | 59 |
| Coloring composition | | | S-50 | S-51 | S-52 | S-53 | S-54 | S-55 | S-56 | S-57 | S-58 | S-59 |
| Pigment dispersion 1 | | Kind | R-18 | R-18 | R-18 | R-18 | R-18 | R-18 | R-18 | R-3 | R-3 | R-3 |
| | | Kind and | R264/ | R264/ | R264/ | R264/ | R264/ | R264/ | R264/ | R264/ | R264/ | R264/ |
| | | proportion | Y185 = | Y185 = | Y185 = | Y185 = | Y185 = | Y185 = | Y185 = | Y185 = | Y185 = | Y185 = |
| | | of colorant | 80/20 | 80/20 | 80/20 | 80/20 | 80/20 | 80/20 | 80/20 | 80/20 | 80/20 | 80/20 |
| | | contained | | | | | | | | | | |
| | | Amount | 21.8 | 21.8 | 21.8 | 21.8 | 21.8 | 21.8 | 21.8 | 21.8 | 21.8 | 21.8 |
| Pigment dispersion 2 | | Kind | | | | | | | | | | |
| | | Kind and | | | | | | | | | | |
| | | proportion | | | | | | | | | | |
| | | of colorant | | | | | | | | | | |
| | | contained | | | | | | | | | | |
| | | Amount | | | | | | | | | | |
| (C) Binder resin | (C1) | C-5 | | | | | | | | | | |
| | | C-6 | | | | | | | | | | |
| | | C-7 | | | | | | | | | | |
| | | C-8 | | | | | | | | | | |
| | (C2) | C-1 | | | | | | | | | | |
| | | C-2 | 0.55 | 0.55 | 0.55 | 0.55 | 0.55 | 0.55 | 0.55 | 0.55 | 0.55 | 0.55 |
| | | C-3 | | | | | | | | | | |
| | | C-4 | | | | | | | | | | |
| (D) Polymerizable | (D1) | D1-1 | 0.65 | 0.65 | 0.65 | 0.65 | 0.65 | 0.65 | 0.65 | | 0.35 | 0.25 |
| compound | | D1-2 | | | | | | | | 0.65 | | |
| | (D2) | D2-1 | | | | | | | | | 0.3 | 0.4 |
| (E) Photopolymerization | (E1) | E1-1 | 0.18 | | | | | | | | | |
| initiator | | E1-2 | | 0.18 | 0.15 | 0.12 | 0.06 | 0.03 | 0.15 | | | |
| | | E1-3 | | | | | | | | 0.18 | 0.18 | 0.18 |
| | (E2) | E2-1 | | | | | | | 0.03 | | | |
| | | E2-2 | | | 0.03 | 0.06 | 0.12 | 0.15 | | | | |
| Additive | (G) | G-1 | 0.1 | 0.1 | 0.1 | 0.1 | 0.1 | 0.1 | 0.1 | 0.1 | 0.1 | 0.1 |
| (F) Solvent | (F1) | PGME | | | | | | | | | | |
| | | PGEE | | | | | | | | | | |
| | | PNP | | | | | | | | | | |
| | | DAA | | | | | | | | | | |
| | | EL | | | | | | | | | | |
| | | CHN | | | | | | | | | | |
| | (F2) | γBL | 7.3 | 7.3 | 7.3 | 7.3 | 7.3 | 7.3 | 7.3 | 7.3 | 7.3 | 7.3 |
| | | EDGAC | | | | | | | | | | |
| | | DPMA | | | | | | | | | | |
| | (F3) | PGMEA | | | | | | | | | | |
| | | EEP | | | | | | | | | | |
| | | MBA | | | | | | | | | | |

| | | | | | | | | | | |
|---|---|---|---|---|---|---|---|---|---|---|
| Proportion of (F1)(%) | 13 | 13 | 13 | 13 | 13 | 13 | 13 | 13 | 13 | 13 |
| Proportion of (F2)(%) | 28 | 28 | 28 | 28 | 28 | 28 | 28 | 28 | 28 | 28 |
| Proportion of (F3)(%) | 59 | 59 | 59 | 59 | 59 | 59 | 59 | 59 | 59 | 59 |
| Concentration of pigment (%) | 50 | 50 | 50 | 50 | 50 | 50 | 50 | 50 | 50 | 50 |
| Sensibility and pattern shape | A | A | A | A | A | A | A | A | A | A |
| Development residues | A | A | A | A | A | A | A | A | B | C |
| Surface roughness | C | C | B | A | A | B | B | A | A | A |
| Film thickness uniformity | A | A | A | A | A | A | A | A | A | A |
| Storage stability of coloring composition | A | A | A | A | A | A | A | A | A | A |

### Preparation Examples 37 to 50

The pigment dispersions (R-37) to (R-50) were prepared in the same manner as in Preparation Example 3 except that the member of the components used was changed as presented in Table 15 in Preparation Example 3.

### Examples 60 to 72

The coloring compositions (S-60) to (S-72) were prepared in the same manner as in Example 3 except that the member of the pigment dispersion used was changed as presented in Table 15 in Example 3. Subsequently, the evaluation was carried out in the same manner as in Example 3. The results thereof are presented in Table 10. The results of the evaluation on transmittance in Examples 60 to 72 are the same as those in Example 3, and the description thereon is thus omitted.

TABLE 15

| | | | Preparation | Preparation | Preparation | Preparation | Preparation | Preparation | Preparation |
|---|---|---|---|---|---|---|---|---|---|
| | | | Example 37 | Example 38 | Example 39 | Example 40 | Example 41 | Example 42 | Example 43 |
| Pigment dispersion | | | R-37 | R-38 | R-39 | R-40 | R-41 | R-42 | R-43 |
| (A) Colorant | | R264 (11 nm) | | | | | | | |
| | | R264 (22 nm) | | | | | | | |
| | | R264 (39 nm) | | | | | | | |
| | | R264 (58 nm) | 8.8 | 88 | 8.8 | 8.8 | 8.8 | 8.8 | 8.8 |
| | | R264 (83 nm) | | | | | | | |
| | | R264 (104 nm) | | | | | | | |
| | | R254 (41 nm) | | | | | | | |
| | | R242 (42 nm) | | | | | | | |
| | | R177 (38 nm) | | | | | | | |
| | | Y185 (12 nm) | | | | | | | |
| | | Y185 (20 nm) | | | | | | | |
| | | Y185 (42 nm) | | | | | | | |
| | | Y185 (60 nm) | 2.2 | 2.2 | 2.2 | 2.2 | 2.2 | 2.2 | 2.2 |
| | | Y185 (81 nm) | | | | | | | |
| | | Y185 (103 nm) | | | | | | | |
| | | Y139 (40 nm) | | | | | | | |
| | | Y150 (41 nm) | | | | | | | |
| | | Y138 (41 nm) | | | | | | | |
| Disperson auxiliary | | α | 0.4 | 0.4 | 0.4 | 0.4 | 0.4 | 0.4 | 0.4 |
| | | β | | | | | | | |
| | | γ | | | | | | | |
| (B) Dispersant | (B1) | Dispersant (B-1) | 8.45 | 8.45 | 8.45 | 8.45 | 8.45 | 8.45 | 8.45 |
| | | LPN6919 | | | | | | | |
| | | LPN21116 | | | | | | | |
| | (B2) | byk2001 | | | | | | | |
| (C) Binder resin | (C1) | C-5 | 4.9 | | | | | | |
| | | C-6 | | 4.9 | | | | | |
| | | C-7 | | | 4.9 | | | | |
| | | C-8 | | | | | | | |
| | (C2) | C-1 | | | | 4.9 | | | |
| | | C-2 | | | | | 4.9 | | |
| | | C-3 | | | | | | 4.9 | |
| | | C-4 | | | | | | | 4.9 |
| (F) Solvent | (F1) | PGME | 15 | 15 | 15 | 15 | 15 | 15 | 15 |
| | | PGEE | | | | | | | |
| | | PNP | | | | | | | |
| | | DAA | | | | | | | |
| | | EL | | | | | | | |
| | | CHN | | | | | | | |
| | (F2) | γBL | | | | | | | |
| | | EDGAC | | | | | | | |
| | | DPMA | | | | | | | |
| | (F3) | PGMEA | 60.25 | 60.25 | 60.25 | 60.25 | 60.25 | 60.25 | 60.25 |
| | | EEP | | | | | | | |
| | | MBA | | | | | | | |
| | | | Preparation | Preparation | Preparation | Preparation | Preparation | Preparation | Preparation |
| | | | Example 44 | Example 45 | Example 46 | Example 47 | Example 48 | Example 49 | Example 50 |
| Pigment dispersion | | | R-44 | R-45 | R-46 | R-47 | R-48 | R-49 | R-50 |
| (A) Colorant | | R264 (11 nm) | | | | | | | |
| | | R264 (22 nm) | | | | | | | |
| | | R264 (39 nm) | | | | | | | |
| | | R264 (58 nm) | 8.8 | 8.8 | 88 | 8.8 | 8.8 | 8.8 | |
| | | R264 (83 nm) | | | | | | | |
| | | R264 (104 nm) | | | | | | | |
| | | R254 (41 nm) | | | | | | | |
| | | R242 (42 nm) | | | | | | | |
| | | R177 (38 nm) | | | | | | | |
| | | Y185 (12 nm) | | | | | | | |
| | | Y185 (20 nm) | | | | | | | |
| | | Y185 (42 nm) | | | | | | | |
| | | Y185 (60 nm) | 2.2 | 2.2 | 2.2 | 2.2 | 2.2 | | 2.2 |
| | | Y185 (81 nm) | | | | | | | |
| | | Y185 (103 nm) | | | | | | | |
| | | Y139 (40 nm) | | | | | | | |
| | | Y150 (41 nm) | | | | | | | |
| | | Y138 (41 nm) | | | | | | | |
| Disperson auxiliary | | α | 0.4 | 0.4 | 0.4 | | | 0.32 | 0.08 |
| | | β | | | | 0.4 | | | |
| | | γ | | | | | 0.4 | | |
| (B) Dispersant | (B1) | Dispersant (B-1) | | | | 8.45 | 8.45 | 6.76 | 1.69 |
| | | LPN6919 | 5.63 | | | | | | |
| | | LPN21116 | | 8.45 | | | | | |
| | (B2) | byk2001 | | | 7.35 | | | | |
| (C) Binder resin | (C1) | C-5 | | | | | | | |
| | | C-6 | | | | | | | |
| | | C-7 | | | | | | | |
| | | C-8 | 4.9 | 4.9 | 4.9 | 4.9 | 4.9 | 3.92 | 0.98 |
| | (C2) | C-1 | | | | | | | |
| | | C-2 | | | | | | | |
| | | C-3 | | | | | | | |
| | | C-4 | | | | | | | |
| (F) Solvent | (F1) | PGME | 15 | 15 | 15 | 15 | 15 | 12 | 3 |
| | | PGEE | | | | | | | |
| | | PNP | | | | | | | |
| | | DAA | | | | | | | |
| | | EL | | | | | | | |
| | | CHN | | | | | | | |
| | (F2) | γBL | | | | | | | |
| | | EDGAC | | | | | | | |
| | | DPMA | | | | | | | |
| | (F3) | PGMEA | 63.07 | 60.25 | 61.35 | 60.25 | 60.25 | 48.2 | 12.05 |
| | | EEP | | | | | | | |
| | | MBA | | | | | | | |

TABLE 16

| | | | Example 60 | Example 61 | Example 62 | Example 63 | Example 64 | Example 65 | Example 66 |
|---|---|---|---|---|---|---|---|---|---|
| Coloring composition | | | S-60 | S-61 | S-62 | S-63 | S-64 | S-65 | S-66 |
| Pigment dispersion 1 | | Kind | R-37 | R-38 | R-39 | R-40 | R-41 | R-42 | R-43 |
| | | Kind and | R264/Y185 = | R264/Y185 = | R264/Y185 = | R264/Y185 = | R264/Y185 = | R264/Y185 = | R264/Y185 = |
| | | proportion | 80/20 | 80/20 | 80/20 | 80/20 | 80/20 | 80/20 | 80/20 |
| | | of colorant | | | | | | | |
| | | contained | | | | | | | |
| | | Amount | 21.8 | 21.8 | 21.8 | 21.8 | 21.8 | 21.8 | 21.8 |
| Pigment dispersion 2 | | Kind | | | | | | | |
| | | Kind and | | | | | | | |
| | | proportion | | | | | | | |
| | | of colorant | | | | | | | |
| | | contained | | | | | | | |
| | | Amount | | | | | | | |
| (C) Binder resin | (C1) | C-5 | | | | | | | |
| | | C-6 | | | | | | | |
| | | C-7 | | | | | | | |
| | | C-8 | | | | | | | |
| | (C2) | C-1 | | | | | | | |
| | | C-2 | 0.55 | 0.55 | 0.55 | 0.55 | 0.55 | 0.55 | 0.55 |
| | | C-3 | | | | | | | |
| | | C-4 | | | | | | | |
| (D) Polymerizable | (D1) | D1-1 | 0.65 | 0.65 | 0.65 | 0.65 | 0.65 | 0.65 | 0.65 |
| compound | | D1-2 | | | | | | | |
| | (D2) | D2-1 | | | | | | | |
| (E) Photopolymerization | (E1) | E1-1 | | | | | | | |
| initiator | | E1-2 | | | | | | | |
| | | E1-3 | 0.18 | 0.18 | 0.18 | 0.18 | 0.18 | 0.18 | 0.18 |
| | (E1) | E2-1 | | | | | | | |
| | | E2-2 | | | | | | | |
| Additive | (G) | G-1 | 0.1 | 0.1 | 0.1 | 0.1 | 0.1 | 0.1 | 0.1 |
| (F) Solvent | (F1) | PGME | | | | | | | |
| | | PGEE | | | | | | | |
| | | PNP | | | | | | | |
| | | DAA | | | | | | | |
| | | EL | | | | | | | |
| | | CHN | | | | | | | |
| | (F2) | γBL | 7.3 | 7.3 | 7.3 | 7.3 | 7.3 | 7.3 | 7.3 |
| | | EDGAC | | | | | | | |
| | | DPMA | | | | | | | |
| | (F3) | PGMEA | | | | | | | |
| | | EEP | | | | | | | |
| | | MBA | | | | | | | |

| | | | | | | | |
|---|---|---|---|---|---|---|---|
| Proportion of (F1) (%) | 13 | 13 | 13 | 13 | 13 | 13 | 13 |
| Proportion of (F2) (%) | 28 | 28 | 28 | 28 | 28 | 28 | 28 |
| Proportion of (F3) (%) | 59 | 59 | 59 | 59 | 59 | 59 | 59 |
| Concentration of pigment (%) | 50 | 50 | 50 | 50 | 50 | 50 | 50 |
| Sensitivity and pattern shape | A | A | A | A | A | A | A |
| Development residues | A | A | A | A | A | A | A |
| Surface roughness | A | A | A | A | B | B | B |
| Film thickness uniformity | A | A | A | A | A | A | A |
| Storage stability of coloring composition | A | A | A | A | A | A | A |

| | | | Example 67 | Example 68 | Example 69 | Example 70 | Example 71 | Example 72 |
|---|---|---|---|---|---|---|---|---|
| Coloring composition | | | S-67 | S-68 | S-69 | S-70 | S-71 | S-72 |
| Pigment dispersion 1 | | Kind | R-44 | R-45 | R-46 | R-47 | R-48 | R-49 |
| | | Kind and | R2641/Y185 = | R264/Y185 = | R264/Y185 = | R264/Y185 = | R264/Y185 = | R264 = 100 |
| | | proportion | 80/20 | 80/20 | 80/20 | 80/20 | 80/20 | |
| | | of colorant | | | | | | |
| | | contained | | | | | | |
| | | Amount | 21.8 | 21.8 | 21.8 | 21.8 | 21.8 | 17.44 |
| Pigment dispersion 2 | | Kind | | | | | | R-50 |
| | | Kind and | | | | | | Y185 = 100 |
| | | proportion | | | | | | |
| | | of colorant | | | | | | |
| | | contained | | | | | | |
| | | Amount | | | | | | 4.36 |
| (C) Binder resin | (C1) | C-5 | | | | | | |
| | | C-6 | | | | | | |
| | | C-7 | | | | | | |
| | | C-8 | | | | | | |
| | (C2) | C-1 | | | | | | |
| | | C-2 | 0.55 | 0.55 | 0.55 | 0.55 | 0.55 | 0.55 |
| | | C-3 | | | | | | |
| | | C-4 | | | | | | |
| (D) Polymerizable | (D1) | D1-1 | 0.65 | 0.65 | 0.65 | 0.65 | 0.65 | 0.65 |
| compound | | D1-2 | | | | | | |
| | (D2) | D2-1 | | | | | | |
| (E) Photopolymerization | (E1) | E1-1 | | | | | | |
| initiator | | E1-2 | | | | | | |
| | | E1-3 | 0.18 | 0.18 | 0.18 | 0.18 | 0.18 | 0.18 |
| | (E1) | E2-1 | | | | | | |
| | | E2-2 | | | | | | |
| Additive | (G) | G-1 | 0.1 | 0.1 | 0.1 | 0.1 | 0.1 | 0.1 |
| (F) Solvent | (F1) | PGME | | | | | | |
| | | PGEE | | | | | | |
| | | PNP | | | | | | |
| | | DAA | | | | | | |
| | | EL | | | | | | |
| | | CHN | | | | | | |
| | (F2) | γBL | 7.3 | 7.3 | 7.3 | 7.3 | 7.3 | 7.3 |
| | | EDGAC | | | | | | |
| | | DPMA | | | | | | |
| | (F3) | PGMEA | | | | | | |
| | | EEP | | | | | | |
| | | MBA | | | | | | |

| | | | | | | |
|---|---|---|---|---|---|---|
| Proportion of (F1) (%) | 13 | 13 | 13 | 13 | 13 | 13 |
| Proportion of (F2) (%) | 28 | 28 | 28 | 28 | 28 | 28 |
| Proportion of (F3) (%) | 59 | 59 | 59 | 59 | 59 | 59 |
| Concentration of pigment (%) | 50 | 50 | 50 | 50 | 50 | 50 |
| Sensitivity and pattern shape | A | B | A | B | B | A |
| Development residues | D | A | A | C | C | A |
| Surface roughness | B | B | C | C | C | B |
| Film thickness uniformity | A | A | A | B | B | A |
| Storage stability of coloring composition | A | A | A | B | B | B |

As described above, the following facts can be said on the coloring composition of the present invention which contains the pigment X and the isoindoline pigment as (A) the colorant as compared to a coloring composition that is known in the prior art and uses, for example, C.I. Pigment Red 177, C.I. Pigment Red 242, or C.I. Pigment Red 254 as a main pigment.

1) It is possible to efficiently shield light in violet to blue since the transmittance at 400, 405, 410, 415, 420, 425, and 430 nm is smaller.

2) It is possible to efficiently shield light in blue to green since the maximum transmittance in a wavelength range of from 430 to 560 nm is smaller.

3) It is possible to fabricate a solid-state imaging element which exhibits favorable color reproducibility since the transmittance at 580 nm is smaller and rising to switch from the absorption region to the transmissive region is thus moderate.

4) It is possible to fabricate a solid-state imaging element which exhibits favorable red color reproducibility since the transmittance at 620 nm is greater and a red color sensing signal is thus sufficiently incorporated.

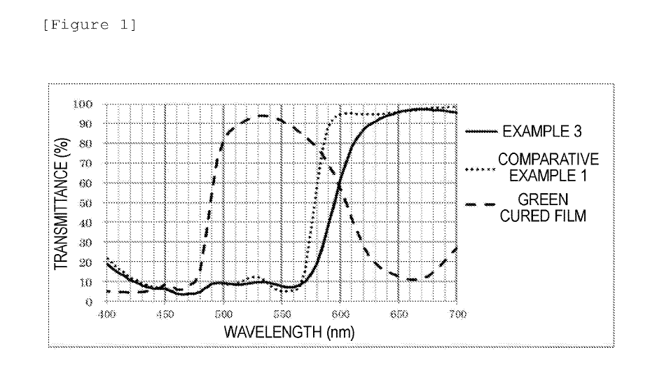

5) As presented in FIG. 1, in the red cured film of Comparative Example 1 which contains C.I. Pigment Red 254/C.I. Pigment Yellow 185=80/20 as the colorant of Comparative Example 1, rising to switch from the absorption region to the transmissive region in the transmission curve is steep, and the transmissive region of the red cured film thus overlaps with that of the green cured film so that the color separation property between the red cured film and the green pixel is easily affected. In contrast, in the red cured film of Example 3 which contains C.I. Pigment Red 264/C.I. Pigment Yellow 185=80/20, rising to switch from the absorption region to the transmissive region in the transmission curve is moderate and the transmissive region of the red cured film thus hardly overlaps with that of the green cured film so that the color separation property between the red cured film and the green pixel is hardly affected.

6) The red cured film of Example 12 having a pigment content of 45 mass % has equal transmittances with the red cured film of Comparative Example 1 having a pigment content of 50 mass % except that the transmittance of the red cured film of Example 12 at 580 nm is superior as compared to that of the red cured film of Comparative Example 1. Hence, the coloring composition of the present invention is able to achieve the color separation property required to a color filter at a lower pigment content.

Consequently, it is possible to form a red pixel which exhibits favorable color reproducibility and hardly affects the transmissive region of a green pixel by using the coloring composition of the present invention, and the coloring composition of the present invention can be extremely suitably used in the fabrication of a solid-state imaging element.

1. A coloring composition comprising:
(A) a colorant;
(C) a binder resin;
(D) a polymerizable compound; and
(F) a solvent;
wherein the colorant (A) comprises:
(A1) a pigment having a structure represented by the following Formula (X):
(A2) an isoindoline pigment;
wherein the solvent (F) comprises (G) at least one member selected from the group consisting of an alcohol, a ketone, and an alkyl lactate: 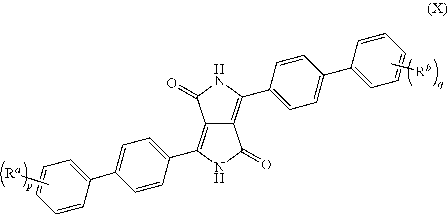
and wherein, in the Formula (X),
R^{a} and R^{b} each independently represent a monovalent organic group, and p and q each independently represent an integer from 0 to 5.

2. The coloring composition according to claim 1, comprising the component (G) at from 3 to 40 mass % with respect to the total amount of solvent.

3. The coloring composition according to claim 1, wherein a mass ratio of the component (A1) to the component (A2) [(A1)/(A2)] is from 85/15 to 65/35.

4. The coloring composition according to claim 1, wherein the component (A2) is C.I. Pigment Yellow 185.

5. The coloring composition according to claim 1, wherein the component (A1) is C.I. Pigment Red 264.

6. The coloring composition according to claim 1, wherein the component (D) contains at least one member selected from the group consisting of a multifunctional (meth)acrylate modified with an alkylene oxide and a multifunctional (meth)acrylate having a carboxyl group.

7. The coloring composition according to claim 1, further comprising (E) a photopolymerization initiator comprising (E1) an O-acyloxime-based compound; and
(E2) at least one member of compound selected from the group consisting of a thioxanthone-based compound and an acetophenone-based compound.

8. The coloring composition according to claim 7, wherein a mass ratio of the component (E1) to the component (E2) [(E1)/(E2)] is from 20/80 to 80/20.

9. The coloring composition according to claim 1, further comprising (B) a dispersant comprising (B1) a dispersant having a repeating unit having an alkylene oxide structure.

10. The coloring composition according to claim 9, wherein a proportion of a repeating unit having an alkylene oxide structure contained in the component (B1) to the total repeating units is from 3 to 40 mass %.

11. The coloring composition according to claim 10, wherein a proportion of a repeating unit having an alkylene oxide structure contained in the component (B1) to the total repeating units is from 13 to 27 mass %.

12. The coloring composition according to claim 1, wherein a proportion of a solvent having a boiling point of 180° C. or higher at 1 atm contained in the component (F) is from 1 to 40 mass %.

13. The coloring composition according to claim 1, wherein an average particle size of a pigment contained in (A) the colorant is from 15 to 100 nm.

14. A colored cured film comprising:
(A1) a pigment having a structure represented by Formula (X); and
(A2) an isoindoline pigment,
wherein the colored cured film meets any one or more of the following criteria (1) to (4) at a film thickness of 0.5 μm:
(1) a transmittance at a wavelength of 400 nm is 30% or less,
(2) a maximum transmittance in a wavelength region of from 430 to 560 nm is 15% or less,
(3) a transmittance at a wavelength of 580 nm is 50% or less, and
(4) a transmittance at a wavelength of 620 nm is 80% or more, 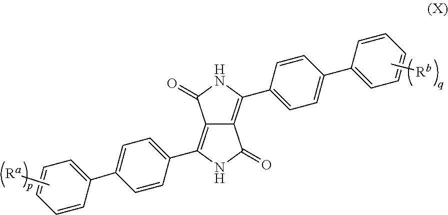
and wherein, in the Formula (X),
R^{a} and R^{b} each independently represent a monovalent organic group, and
p and q each independently represents an integer from 0 to 5.

15. A solid-state imaging element comprising the colored cured film according to claim 14.
